(19) United States
(12) Patent Application Publication
(10) Pub. No.: US 2022/0243325 A1
(43) Pub. Date: Aug. 4, 2022

(54) Rotating Disk Reactor with Split Substrate Carrier

(71) Applicant: Veeco Instruments, Inc., Plainview, NY (US)

(72) Inventors: Sandeep Krishnan, Jersey City, NJ (US); Alexander I. Gurary, Bridgewater, NJ (US); Yuliy Rashkovsky, Milburn, NJ (US); Robert Scott Maxwell IV, Brooklyn, NY (US); Aniruddha Bagchi, Belle Mead, NJ (US)

(73) Assignee: Veeco Instruments, Inc., Plainview, NY (US)

(21) Appl. No.: 17/717,679

(22) Filed: Apr. 11, 2022

Related U.S. Application Data
(63) Continuation-in-part of application No. 16/752,661, filed on Jan. 26, 2020.
(60) Provisional application No. 62/801,241, filed on Feb. 5, 2019.
(60) Provisional application No. 62/801,288, filed on Feb. 5, 2019.

(51) Int. Cl. C23C 16/458; H01L 21/673; H01L 21/687

(52) U.S. Cl. CPC C23C 16/4585; C23C 16/4584; H01L 21/68785; H01L 21/67346

(57) ABSTRACT

A self-centering split substrate carrier that supports a semiconductor substrate in a CVD system includes a first section configured to be centrally located in the split substrate carrier having a top surface with a recessed area for receiving a substrate for CVD processing and comprising a plurality of apertures positioned in an outer surface. A second section formed in a ring-shape having an inner surface configured to receive the first section and an outer surface configured to interface with an edge drive rotation mechanism that rotates the substrate carrier. The inner surface comprising a plurality of boss structures, wherein a respective one of the plurality of boss structures on the inner surface of the second section is configured to fit into a respective one of the plurality of apertures positioned in the outer surface of the first section, so as to improve alignment of the first and the second section of the self-centering split substrate carrier.

### CROSS REFERENCE TO RELATED APPLICATION

The present application is a continuation-in-part of U.S. patent application Ser. No. 16/752,661 filed on Jan. 26, 2020, which is a non-provisional application of U.S. Provisional Patent Application No. 62/801,241, filed on Feb. 5, 2019, entitled “Rotating Disk Reactor with Self-Locking Carrier-to-Support Interface for Chemical Vapor Deposition” and also is a non-provisional application of U.S. Provisional Patent Application No. 62/801,288, filed on Feb. 5, 2019 entitled “Self-Centering Split-Substrate Carrier System for Chemical Vapor Deposition”. In addition, the present application is also related to U.S. patent application Ser. No. 15/178,723, entitled “Self-Centering Wafer Carrier System for Chemical Vapor Deposition”, filed on Jun. 10, 2016, which claims priority to U.S. Provisional Patent Application No. 62/298,540 entitled “Self-Centering Wafer Carrier System for Chemical Vapor Deposition”, filed on Feb. 23, 2016; U.S. Provisional Patent Application Ser. No. 62/241,482, entitled “Self-Centering Wafer Carrier System for Chemical Vapor Deposition”, filed Oct. 14, 2015; and U.S. Provisional Patent Application Ser. No. 62/183,166, entitled “Self-Centering Wafer Carrier System for Chemical Vapor Deposition”, filed Jun. 22, 2015. The entire contents of U.S. patent application Ser. No. 15/178,723 and U.S. Provisional Patent Application Nos. 62/801,241, 62/801,288, 62/298,540, 62/241,482, and 62/183,166 and are herein incorporated by reference.

The section headings used herein are for organizational purposes only and should not be construed as limiting the subject matter described in the present application in any way.

### INTRODUCTION

Many material processing systems include substrate carriers for supporting substrates during processing. The substrate is often a disc of crystalline material that is commonly called a wafer or substrate. One such type of material processing system is a vapor phase epitaxy (VPE) system. Vapor phase epitaxy is a type of chemical vapor deposition (CVD) which involves directing one or more gases containing chemical species onto a surface of a substrate so that the reactive species react and form a film on the surface of the substrate. For example, VPE can be used to grow compound semiconductor materials on substrates.

Materials are typically grown by injecting at least one precursor gas and, in many processes, at least a first and a second precursor gas into a process chamber containing the crystalline substrate. Compound semiconductors, such as III-V semiconductors, can be formed by growing various layers of semiconductor materials on a substrate using a hydride precursor gas and an organometallic precursor gas. Metalorganic vapor phase epitaxy (MOVPE) is a vapor deposition method that is commonly used to grow compound semiconductors using a surface reaction of metalorganics and hydrides containing the required chemical elements. For example, indium phosphide could be grown in a reactor on a substrate by introducing trimethylindium and phosphine.

Alternative names for MOVPE used in the art include organometallic vapor phase epitaxy (OMVPE), metalorganic chemical vapor deposition (MOCVD), and organometallic chemical vapor deposition (OMCVD). In these processes, the gases react with one another at the growth surface of a substrate, such as a sapphire, Si, GaAs, InP, InAs or GaP substrate, to form a III-V compound of the general formula In_{X}Ga_{Y}Al_{Z}N_{A}As_{B}P_{C}Sb_{D}, where X+Y+Z equals approximately one, A+B+C+D equals approximately one, and each of X, Y, Z, A, B, C, and D can be between zero and one. In various processes, the substrate can be a metal, semiconductor, or an insulating substrate. In some instances, bismuth may be used in place of some or all of the other Group III metals.

Compound semiconductors, such as III-V semiconductors, can also be formed by growing various layers of semiconductor materials on a substrate using a hydride or a halide precursor gas process. In one halide vapor phase epitaxy (HVPE) process, Group III nitrides (e.g., GaN, AlN) are formed by reacting hot gaseous metal chlorides (e.g., GaCl or AlCl) with ammonia gas (NH₃). The metal chlorides are generated by passing hot HCl gas over the hot Group III metals. One feature of HVPE is that it can have a very high growth rate, up to 100 μm per hour for some state-of-the-art processes. Another feature of HVPE is that it can be used to deposit relatively high quality films because films are grown in a carbon free environment and because the hot HCl gas provides a self-cleaning effect.

In these processes, the substrate is maintained at an elevated temperature within a reaction chamber. The precursor gases are typically mixed with inert carrier gases and are then directed into the reaction chamber. Typically, the gases are at a relatively low temperature when they are introduced into the reaction chamber. As the gases reach the hot substrate, their temperature, and hence their available energy for reaction, increases. Formation of the epitaxial layer occurs by final pyrolysis of the constituent chemicals at the substrate surface. Crystals are formed by a chemical reaction on the surface of the substrate and not by physical deposition processes. Consequently, VPE is a desirable growth technique for thermodynamically metastable alloys. Currently, VPE is commonly used for manufacturing laser diodes, solar cells, and light emitting diodes (LEDs) as well as power electronics.

It is highly desirable in CVD deposition to be able to deposit highly uniform films across the entire substrate. The presence of non-uniform temperature profiles across the substrate during deposition leads to non-uniform deposited films. Methods and apparatus that improve uniformity of the thermal profile across the substrate over the duration of the deposition are needed to improve yield.

### SUMMARY OF THE INVENTION

A substrate carrier that supports at least one semiconductor wafer in a chemical vapor deposition system that includes a support having a beveled inner top surface including a top surface and a bottom surface. The top surface has a recessed area for receiving at least one substrate for chemical vapor deposition processing. The bottom surface has a beveled edge that forms a conical interface with the beveled inner top surface of the support at a self-locking angle that prevents substrate carrier movement in a vertical direction at a predetermined temperature equal to a maximum operation temperature. The self-locking angle can be determined by the expression tan α>f, where α is the self-locking angle and f is the coefficient of friction. In various embodiments, the self-locking angle ranges from about 5 to about 40 degrees, ranges from about 15 to about 30 degrees, or ranges from about 15 to about 25 degrees.

The bottom surface having the beveled edge that forms the conical interface with the beveled inner top surface of the support can be configured to provide a small gap at the conical interface at room temperature. The bottom surface having the beveled edge that forms the conical interface with the beveled inner top surface of the support can also be configured to provide a substantially zero gap between the substrate carrier and the support at the conical interface at temperature ranging from about 500° C. to about 900° C. Also, the bottom surface having the beveled edge that forms the conical interface with the beveled inner top surface of the support can also be configured to provide a negative gap between the substrate carrier and the rotating support that is less than 0.05 mm at a temperature ranging from about 1000° C. to about 1150° C. The negative gap results from the beveled edge of the substrate carrier expanding into the beveled inner top surface of the support.

In some embodiments, the substrate carrier can be a split substrate carrier. The split substrate carrier configuration mechanically decouples a first section of the carrier from a second section of the carrier. A split substrate carrier includes a first section that is circularly shaped like a central “puck” that is centrally located. The first section comprises a top surface having a recessed area for receiving a substrate for chemical vapor deposition processing. In addition, the split substrate carrier includes a second section that is shaped like an outer edge ring that is positioned around the circularly-shaped first section.

The first section can support an entire bottom surface of the substrate or can support the substrate at a perimeter of the substrate, leaving a portion of a bottom surface of the substrate exposed. The second section of the split substrate carrier is positioned around the circularly-shaped first section to form an outer edge ring that is configured to interface with an edge drive rotation mechanism, such as a rotating tube. A radial clearance between the first and second sections of the split substrate carrier can be in the range of 100-500 microns. The second section of the split substrate carrier can include an outer ledge and an inner ledge having a flat portion where the circularly-shaped first section rests.

The first and the second sections of the split substrate carrier can be formed of materials with the same coefficients of thermal expansion or materials with different coefficients of thermal expansion. At least one of the first and the second sections of the split substrate carrier can be formed of molybdenum, titanium zirconium molybdenum, or can be formed of at least one of SiC coated graphite and TaC coated graphite.

The top surface of the first section and the top surface of the second section of the split substrate carrier can each comprise a plurality of dimples, notches, protrusion, and/or similar structures that are positioned proximate to an interface between the first and second sections of the split substrate carrier. The plurality of structures can be configured to provide angular alignment of the first section of the split substrate carrier relative to the second section of the split substrate carrier. The first section of the split substrate carrier can also include a plurality of boss structures and the second section of the split substrate carrier can include a plurality of corresponding apertures, where a respective one of the plurality of boss structures is positioned to interface with a respective one of the plurality of apertures so that the first and second sections of the split substrate carrier are centered concentrically while allowing for radial thermal expansion of the first section relative to the second section.

In some embodiments of the present teaching that include a split substrate carrier, the first and second sections of the split substrate carrier are configured to form a gap there between, the gap being dimensioned to create a labyrinthine gas flow path between the first and the section of the split substrate carrier that reduces gas diffusion from a reaction space proximate to the top surface of the first section of the split substrate carrier and to form a heater volume proximate to a bottom surface of first section of the split substrate carrier.

In embodiments of the present teaching that include a split substrate carrier, it is the second section of the split substrate carrier that includes a bottom surface having a beveled edge that forms a conical interface with the beveled inner top surface of the support.

In some embodiments of the present teaching, the edges of the bottom surface of the substrate carrier is chosen to provide a coincident alignment of a central axis of the substrate carrier and a rotation axis of the rotating tube during process at a desired process temperature that may establish an axial-symmetrical temperature profile across the substrate and/or provide a rotation eccentricity of the substrate is substantially zero at the desired process temperature.

In some embodiments of the present teaching, the edge geometry of the beveled edge of the bottom surface of the substrate carrier and the edge geometry of the rotating tube are chosen to define matching bevel surfaces. The matching bevel surfaces are parallel. The matching bevel surfaces can be at an angle α with respect to a vertical sidewall of the rotating tube such that tan(α)>f, where f is a coefficient of friction between the second section of the split substrate carrier and the rotating tube.

Embodiments of the substrate carrier system of the present teaching can also include a separator that provides radiant heating to the substrate. The separator can include a geometry chosen to provide centering of the separator with respect to a center of the rotating tube. The separator geometry can also be chosen to cause the separator to remain static with respect to the rotating tube during rotation.

In some embodiments, a coefficient of thermal expansion of a material forming the substrate carrier is similar to as a coefficient of thermal expansion of a material forming the support. In some embodiments, the support is formed of the same material as the substrate carrier.

A method of manufacturing a substrate carrier that supports at least one semiconductor wafer on a top surface of the substrate carrier in a chemical vapor deposition system at a desired self-locking angle α includes providing a cylindrical support having a beveled inner top surface. A beveled edge that defines a conical interface with the beveled inner top surface of the cylindrical support is formed on a bottom surface of the substrate carrier. A coefficient of friction is measured at the conical interface. The self-locking angle α is determined from the expression tan α>f, where f is the measured coefficient of friction at the conical interface. A bottom surface of another substrate carrier is then formed at a beveled edge that defines a conical interface with the beveled inner top surface of the cylindrical support at the determined self-locking angle α. Some embodiments of the method include manufacturing the substrate carrier as a single piece. Other embodiments of the method include manufacturing the substrate carrier with a first and second section such that the first section is mechanically decoupled from the second section of the carrier and the first section is circularly shaped like a central “puck” and is centrally located and includes a top surface having a recessed area for receiving a substrate and the second section is shaped like an outer edge ring that is positioned around the circularly-shaped first section.

### BRIEF DESCRIPTION OF THE DRAWINGS

The present teaching, in accordance with preferred and exemplary embodiments, together with further advantages thereof, is more particularly described in the following detailed description taken in conjunction with the accompanying drawings. The skilled person in the art will understand that the drawings, described below, are for illustration purposes only. The drawings are not necessarily to scale; emphasis instead generally being placed upon illustrating principles of the teaching. In the drawings, like reference characters generally refer to like features and structural elements throughout the various figures. The drawings are not intended to limit the scope of the Applicants' teaching in any way.

FIG. 1A illustrates a single substrate CVD reactor comprising a substrate carrier and rotating tube with a multi-zone heater assembly.

FIG. 1B illustrates an expanded-view of a known vertical interface between a substrate carrier and a support.

FIG. 2 illustrates an embodiment of a single substrate CVD reactor of the present teaching comprising a split substrate carrier and rotating tube with heater assembly.

FIG. 3A illustrates a diagram of a CVD reactor that does not use a self-centering technique.

FIG. 3B illustrates a diagram of an embodiment of a CVD reactor of the present teaching with self-centering.

FIG. 4 illustrates a self-centering split substrate carrier CVD system of the present teaching with a pocketless substrate carrier that has an edge with a beveled geometry and a rim.

FIG. 5A illustrates other details of various embodiments of the post and the contact interface shown in FIG. 4 including details of the substrate, the substrate carrier, and the post interface of the substrate carrier.

FIG. 5B illustrates yet other details of various embodiments of the post and the contact interface as shown in FIG. 4 including details of the substrate, the substrate carrier, and the post interface of substrate carrier.

FIG. 6 illustrates an isometric view of a split substrate support ring embodiment according to the present teaching.

FIG. 6A illustrates a cross-section of the substrate support ring of FIG. 6 along line A-A.

FIG. 7 illustrates a cross-section of the split substrate support ring of FIG. 6 mounted on a rotating tube according to the present teaching.

FIG. 7A illustrates a close-up view of circle A in FIG. 7.

FIG. 8 illustrates an exploded view of the substrate support ring and rotating support described in connection with FIGS. 6, 6A, 7 and 7A according to the present teaching.

FIG. 9 illustrates a schematic side-view of a self-centering substrate carrier supported by a rotating support according to the present teaching.

FIG. 10A is an expanded cross-sectional view of an embodiment of a self-centering substrate carrier and rotating support at room temperature according to the present teaching.

FIG. 10B is an expanded cross-sectional view of an embodiment of a self-centering substrate carrier and rotating support at 600° C. according to the present teaching.

FIG. 10C is an expanded cross-sectional view of an embodiment of a self-centering substrate carrier and rotating support according to the present teaching at 750° C., which is a common operating temperature for CVD processes for fabrication multiple quantum well structures.

FIG. 10D is an expanded cross-sectional view of an embodiment of a self-centering substrate carrier and rotating support according to the present teaching at 1150° C., which is a common maximum operating temperature for CVD processes.

FIG. 11 illustrates an expanded cross-sectional view of an embodiment of a self-centering substrate carrier and rotating support that illustrates a conical interface according to the present teaching.

FIG. 12 illustrates an expanded cross-sectional view of an embodiment of a self-centering substrate carrier and rotating support with a conical interface that has a self-locking angle according to the present teaching.

FIG. 13A illustrates an expanded cross-sectional view of an embodiment of a conical interface between the substrate carrier and the rotating support that is configured at a self-locking angle according to the present teaching with a small initial gap during room temperature.

FIG. 13B illustrates an expanded cross-sectional view of an embodiment of a conical interface between the substrate carrier and the rotating support that is configured at a self-locking angle according to the present teaching with a substantially zero initial gap at about 750 degrees C.

FIG. 13C illustrates an expanded cross-sectional view of an embodiment of a conical interface between the substrate carrier and the rotating support that is configured at a self-locking angle according to the present teaching with a substantially zero initial gap at about 1100 degrees C.

FIG. 14 illustrates a graph of temperature as a function of distance across a substrate carrier for a rotating disk reactor configuration with a conical interface between the substrate carrier and the rotating support that is configured at a self-locking angle according to the present teaching.

FIG. 15A illustrates a cross-sectional view of a self-centering split substrate carrier according to the present teaching.

FIG. 15B illustrates an expanded cross-sectional view at one edge of the self-centering split substrate carrier according to the present teaching that was described in connection with FIG. 15A.

FIG. 15C illustrates a top perspective view of the self-centering split substrate carrier described in connection with FIG. 15A.

FIG. 16A illustrates a cross-sectional view of another self-centering split substrate carrier according to the present teaching.

FIG. 16B illustrates an expanded cross-sectional view at one edge of the self-centering split substrate carrier according to the present teaching that was described in connection with FIG. 16A.

FIG. 16C illustrates a top perspective view of the self-centering split substrate carrier described in connection with FIG. 16A.

FIG. 16D illustrates an expanded top perspective view of the self-centering split substrate carrier described in connection with FIGS. 16A and 16B.

FIG. 17A illustrates a perspective view of a first section of the self-centering split substrate carrier that is circularly shaped like a central “puck” and configured to be centrally located in the substrate carrier with alignment features according to the present teaching.

FIG. 17B illustrates a perspective view of a second section of the self-centering split substrate carrier that is shaped like an outer edge ring with alignment features according to the present teaching.

FIG. 17C illustrates a perspective cross-sectional view of a substrate carrier that has a section shaped like an outer edge ring with alignment features according to the present teaching.

FIG. 17D illustrates an expanded perspective cross-sectional view of an interface between a circularly shaped first section and a second section shaped like an outer edge ring according to the present teaching.

FIG. 18A illustrates a perspective view of a first section of another self-centering split substrate carrier that is circularly shaped like a central “puck” and configured to be centrally located in the substrate carrier with alignment features according to the present teaching.

FIG. 18B illustrates a perspective view of a second section of the other self-centering split substrate carrier that is shaped like an outer edge ring with alignment features according to the present teaching.

FIG. 18C illustrates a perspective cross-sectional view of the other substrate carrier that has a section shaped like an outer edge ring with alignment features according to the present teaching.

FIG. 18D illustrates an expanded perspective cross-sectional view of the other interface between a circularly shaped first section and a second section shaped like an outer edge ring according to the present teaching.

### DESCRIPTION OF VARIOUS EMBODIMENTS

The present teaching will now be described in more detail with reference to exemplary embodiments thereof as shown in the accompanying drawings. Reference in the specification to “one embodiment” or “an embodiment” means that a particular feature, structure, or characteristic, described in connection with the embodiment, is included in at least one embodiment of the teaching. The appearances of the phrase “in one embodiment” in various places in the specification are not necessarily all referring to the same embodiment.

It should be understood that the individual steps used in the methods of the present teachings may be performed in any order and/or simultaneously, as long as the teaching remains operable. Furthermore, it should be understood that the apparatus and methods of the present teachings can include any number, or all, of the described embodiments, as long as the teaching remains operable.

While the present teaching is described in conjunction with various embodiments and examples, it is not intended that the present teachings be limited to such embodiments. On the contrary, the present teachings encompass various alternatives, modifications, and equivalents, as will be appreciated by those of skill in the art. Those of ordinary skill in the art, having access to the teaching herein, will recognize additional implementations, modifications, and embodiments, as well as other fields of use, which are within the scope of the present disclosure as described herein.

Recently, there has been tremendous growth in the LED and OLED markets. Also, there have been significant advances in power semiconductors, which have increased their utility. Consequently, there has been an increased demand for efficient and high throughput CVD and MOCVD manufacturing systems and methods to fabricate these devices. There is a particular need for manufacturing systems and methods that improve deposition uniformity without negatively impacting the maintenance and operating parameters, such as rotation rate of the substrate carrier. It is well known that the presence of non-uniform temperature profiles across the substrate during deposition leads to non-uniform deposited films.

The present teaching relates to methods and apparatus for chemical vapor deposition, including MOCVD. More particularly, the present teaching relates to methods and apparatus for chemical vapor deposition using vertical reactors in which the substrates are located on a substrate carrier that is positioned on a rotating cylinder or tube that serves as a rotating support comprising an edge that supports the substrate carrier.

Various aspects of the present teaching are described in connection with a single substrate CVD reactor. However, one skilled in the art will appreciate that the methods and apparatus of the present teaching can be implemented with a multi-substrate reactor. In addition, the CVD reactor and substrate carrier of the present teaching can be scaled to any size substrate.

Also, various aspects of the present teaching are described in connection with a support for the substrate carrier in the CVD reactor that supports the various embodiments of the substrate carrier. The support is referred to in the art and this disclosure by various terms such as “support”, “cylindrical support”, “rotating support”, “drum”, rotating drum” “tube”, “rotating tube”, “drum” or “rotating drum”.

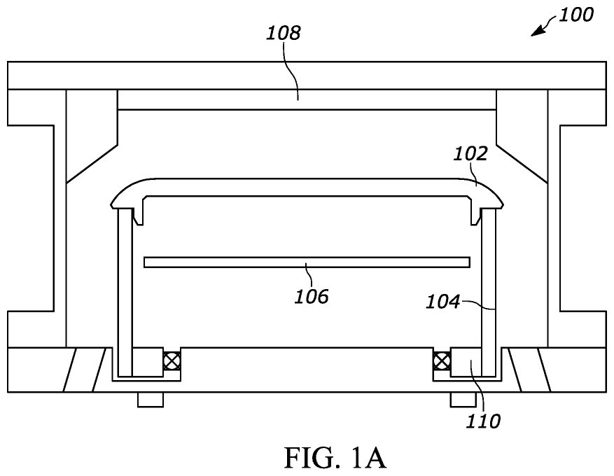

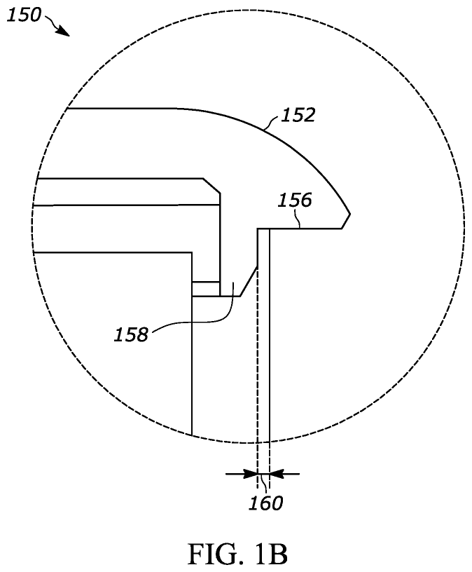

FIG. 1A illustrates a single substrate CVD reactor 100 comprising a substrate carrier 102 and a rotating tube 104 with a multi-zone heater assembly 106. The substrate carrier 102 is supported at the perimeter by the rotating tube 104. In some embodiments, the substrate carrier comprises a rounded edge having a shape that reduces thermal loss and increases uniformity of process gasses flowing over the substrate. The multi-zone heating assembly 106 is positioned under the substrate carrier 102 inside the rotating tube 104 and includes at least two independently controllable heating zones. The multi-zone heater assembly 106 controls the temperature of the substrate carrier to a desired temperature for chemical vapor deposition process. A gas manifold 108 is positioned over the substrate carrier 102 so as to distribute process gasses into a reaction area proximate to the top surface of the substrate carrier that is proximate to the substrate carrier 102. A motor 110 rotates the tube 104.

In this configuration, there is a typically a diametral gap between the substrate carrier 102 and the rotating tube 104 that allows for carrier loading. The width of this gap can change during heating because the substrate carrier 102 and the rotating tube 104 can have different coefficients of thermal expansion (CTE) resulting in different expansions as a function of temperature.

Substrate carriers 102 and rotating tubes 104 can be formed from a variety of materials such as, for example, silicon carbide (SiC), boron nitride (BN), boron carbide (BC), aluminum nitride (AlN), alumina (Al₂O₃), sapphire, silicon, gallium nitride, gallium arsenide, quartz, graphite, graphite coated with silicon carbide (SiC), other ceramic materials, and combinations thereof. In addition, these and other materials can have a refractory coating, for example, a carbide, nitride or oxide refractory coating. Furthermore, the substrate carrier 102 and rotating tubes 104 can be formed from refractory metals, such as molybdenum, tungsten, and alloys thereof. Each of these materials, with or without coating, will have different coefficients of thermal expansion (CTE).

For example, the coefficient of thermal expansion (CTE) of SiC coated graphite, which is commonly used for the substrate carrier, is −5.6×10-6° C.⁻¹. The coefficient of thermal expansion of quartz, which is commonly used as the rotating tube, is −5.5×10-7° C.⁻¹. The coefficient of thermal expansion of CVD SiC is −4.5×10-6° C.⁻¹. Given these coefficients of thermal expansion, an initial gap between the substrate carrier and the rotating tube at room temperature of about 0.5 mm reduces to about 0.05 mm at 1100° C. A small gap at high operating temperatures is required to maintain the integrity of the quartz tube. Because of the changing gap width, known substrate carrier designs do not spin around the geometrical center of the substrate carrier as the temperature increases. This leads to an undesirable linear, or asymmetric, temperature distribution along the substrate carrier radius. Asymmetric temperature non-uniformities cause deposition uniformities which cannot be compensated by multi-zone heating systems. Consequently, known substrate carriers for CVD reactors suffer from non-uniform asymmetric temperature profiles which result from the substrate carrier not rotating around its geometrical center.

FIG. 1B illustrates an expanded-view of a known vertical interface between the substrate carrier 152 and the rotating support 104 (FIG. 1A). Referring to both FIGS. 1A and 1B, the substrate carrier 152 rests on the top of the rotating support 104 at interface 156. The substrate carrier 152 also includes a vertical rim 158 that is aligned with the inside surface of the rotating support 104 so that a small gap 160 is formed between the outer surface of the vertical rim 158 and the insider surface of the rotating support 104. This small gap 160 changes as the operating temperature changes due to the different thermal coefficients of expansion of the substrate carrier 152 material and the rotating support 104 material. If the gap 160 is not wide enough at operating temperatures, the substrate carrier 152 and/or the rotating support 104 could crack or be damaged. If the gap 160 is too wide at operating temperatures, the substrate carrier 152 will wobble due to the eccentricity thereby resulting in non-uniform deposition of materials.

As described in U.S. Patent Publication No. 20150075431 A1, which is assigned to the present assignee, the vertical rim 158 can be positioned and dimensioned such that the substrate carrier 152 does not wobble significantly when it is rotating at the desired rotation rate during normal processing conditions. This can be accomplished by selecting a material for the rotating support 104 that has a coefficient of thermal expansion which is very low compared with the coefficient of thermal expansion of the substrate carrier 152. In this configuration, as the temperature of the substrate carrier 152 is ramped up to the processing temperature, the substrate carrier 152 expands and the gap 160 between the vertical rim 158 and the inside wall of the rotating support 104 reduces, thereby holding the substrate carrier 152 more firmly and reducing wobble.

For example, a SiC coated graphite substrate carrier 152 and a quartz rotating support 104 can be configured to have a 1.5 mm gap at room temperature that reduces to a 1 mm gap at 750 degrees C. and that reduces to 0.1 mm at 1100 degrees C. These small gaps at operating temperate will be sufficient to prevent damage to the quartz rotating support 104 and will reduce wobble in the substrate carrier 152. This technique for configuring the substrate carrier 152 and rotating support 104 so that the substrate carrier 152 expands and the gap 160 between the vertical rim 158 and the inside wall of the rotating support 104 reduces, thereby holding the substrate carrier 152 more firmly and reducing substrate carrier eccentricity or wobble is sometimes referred to as self-centering.

Reducing substrate carrier eccentricity is desirable because substrate carrier eccentricity can cause an asymmetric temperature profile across the substrate carrier, which can affect CVD deposition properties. Reducing substrate carrier tilt is also desirable. One factor resulting in substrate carrier tilt is horizontal forces acting on the substrate carrier.

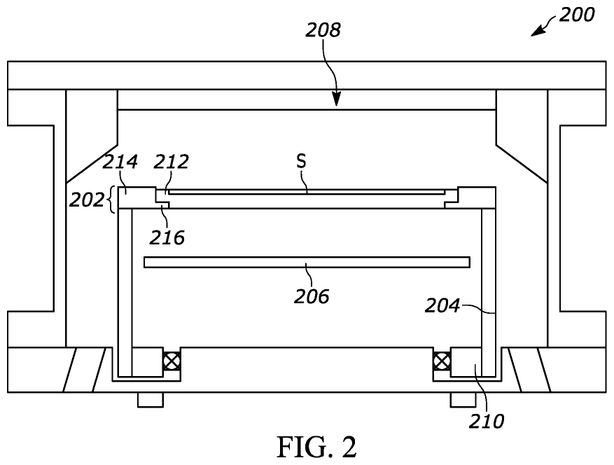

FIG. 2 illustrates an embodiment of a single substrate CVD reactor 200 of the present teaching comprising a split substrate carrier 202 and rotating tube 204 with heater assembly 206. The heater assembly 206 may be a multi-zone heater assembly. The split substrate carrier 202 comprises a first section 212 and a second section 214. The first section 212 is supported by second section 214 with ledge 216. Second section 214 is supported at the perimeter by the rotating tube 204, which can also be referred to more generally as a rotating support, or alternatively as a rotating tube, rotating disk, or a rotating drum. The multi-zone heating assembly 206 is positioned under the substrate carrier 202 inside the rotating tube 204. A gas manifold 208 is positioned over substrate S and over the split substrate carrier 202 so as to distribute process gasses into a reaction area proximate to the top surface of the split substrate carrier 202 proximate to the split substrate carrier 202. A motor 210 rotates tube 204. In this configuration, there is a diametral gap between the substrate carrier 202 and the rotating tube 204 that allows for carrier loading. The width of this gap changes during heating because the substrate carrier 202 and the rotating tube 204 have different coefficients of thermal expansion (CTE) resulting in different expansions as a function of temperature.

The first section 212 and the second section 214 of the split substrate carrier 202 and the rotating tube 204 can be formed from a variety of materials such as, for example, silicon carbide (SiC), boron nitride (BN), boron carbide (BC), aluminum nitride (AlN), alumina (Al₂O₃), sapphire, niobium carbide, niobium nitride, silicon, gallium nitride, gallium arsenide, quartz, graphite, graphite coated with silicon carbide (SiC), other ceramic materials, and combinations thereof. In addition, these and other materials can have a refractory coating, for example, a carbide, nitride or oxide refractory coating. Furthermore, the substrate carrier and rotating tube can be formed from refractory metals, such as molybdenum, tungsten, and alloys thereof. As described above, each of these materials, with or without coating, will have different coefficients of thermal expansion (CTE).

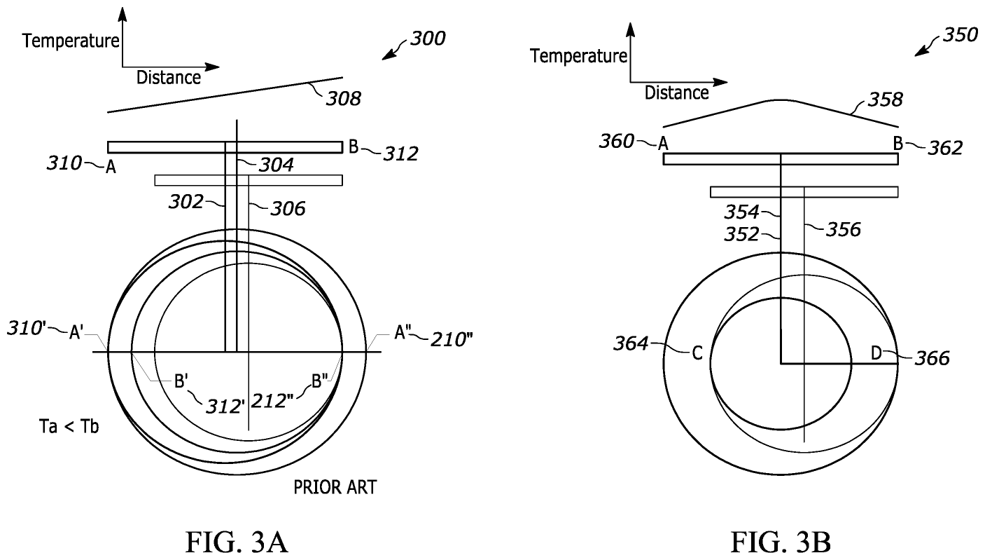

FIG. 3A illustrates a diagram of a CVD reactor that does not use a self-centering technique. FIG. 3A illustrates both a side-view and a plan-view of the relative positions of a substrate carrier, rotation axis, and heater for a CVD reactor 300 for a configuration where the substrate carrier center axis 302 is not coincident with the rotation axis 304 of the rotating support. For purposes of this disclosure, a substrate carrier center axis, which is also sometimes referred to as a central axis, is defined herein as a line centered at the mid-point of the substrate carrier, and extending in a direction normal to the top of the substrate carrier. In this configuration, the substrate carrier center axis 302 is offset from the rotation axis 304 of the rotating support (not shown) and both the substrate carrier center axis 302 and the rotation axis 304 of the rotating support are offset from the heater center 306. Consequently, when the substrate carrier is rotated, the point A 310 and point B 312 travel in different concentric circular paths. More specifically, the point A 310 moves from one far edge of the rotation drum to another far edge as shown by the position of points A′ 310′ and A″ 310″. The point B 312, which is closer to the rotation axis 304 moves from a more inner point of the rotation drum to another more inner point as shown by the position of points B′ 312′ and B″ 312″. In this way, the two points A 310 and B 312 experience different average temperatures on rotation, which leads to an asymmetric temperature profile 308. The asymmetric temperature profile 308 shows a higher temperature on one edge of the substrate, coincident with point B 312 as compared to the temperature on the opposite edge of the substrate coincident with point A 310.

Thus, in the configuration illustrated in FIG. 3A, the average temperature of point A 310, Tₐ, is less than the average temperature of point B 312, T_{b}, which creates a tilted asymmetric temperature profile 308. The asymmetric temperature profile 308 shows a higher temperature on the edge at point B 312 of the substrate as compared to the temperature on the opposite edge of the substrate at point A 310. Thus, the resulting temperature profile is asymmetric with respect to the rotation axis. Even in configurations where the carrier axis is coincident with the heater axis, substrate motion eccentricity owing to an offset between the carrier axis and the rotation axis still leads to asymmetric temperature non-uniformity.

FIG. 3B illustrates a diagram of an embodiment of a CVD reactor with self-centering according to the present teaching. FIG. 3B illustrates a side-view and plan-view of the relative positions of a substrate carrier, rotation axis, and heater for a CVD reactor 350 in the configuration where the substrate carrier center axis 352 is coincident with the rotation axis 354. Coincident alignment of the substrate carrier center axis 352 and the rotation axis 354 as described herein means that the two axes fall on the same line. The position of the substrate carrier center axis 352 relative to the rotation axis 354 of the rotating support (not shown) is coincident, but offset from the heater center position 356. When the substrate carrier center axis 352 and the rotation axis 354 are coincident, even if they are offset from the heater center, the substrate carrier is spinning around the rotation axis with no eccentricity. This configuration leads to a symmetrical temperature profile 358.

More specifically, in this configuration, when the carrier is rotated, the point A 360 and the point B 362 experience the same average temperature from the heater. Similarly, the point C 364 and the point D 366 also experience the same average temperature. However, the average temperature at points C 364 and D 366 are different from the average temperature of points A 360 and B 362. The resulting temperature profile 358 is axially symmetric, but non-uniform.

The uniformity of a film deposited with an axially symmetric non-uniform temperature profile 358 resulting from a self-centering substrate carrier of the present teaching can be improved by properly configuring and operating a multi-zone heater positioned proximate to the substrate carrier. Alternatively, or in combination with proper use of a multi-zone heater positioned proximate to the substrate carrier, the film uniformity resulting from axially symmetric non-uniform temperature profile 358 of the present teaching can be improved by carrier pocket profiling for substrate temperature uniformity. See, for example, U.S. Pat. No. 8,486,726, entitled “Method for Improving Performance of a Substrate Carrier”, which is assigned to the present assignee. The entire specification of U.S. Pat. No. 8,486,726 is incorporated herein by reference. Thus, an axially symmetric non-uniform temperature profile is more desirable than a non-symmetric profile, since known methods and apparatus for thermal management can be used to improve thermal uniformity and the resulting film deposition uniformity.

One feature of the present teaching is that a substrate carrier according to the present teaching can provide coincidence of the substrate carrier central axis and the rotation axis of the rotating support at process temperature. This coincidence reduces eccentricity of the circular rotation of the substrate in order to create an axially symmetric temperature profile that can be compensated for by properly using multi-zone heating elements.

Another feature of the present teaching is that the geometry of the edge of the substrate carrier and the geometry of the edge of the rotating support create a particular amount of eccentric or nearly eccentric rotation of the substrate during processing at process temperature. The amount of eccentric or nearly eccentric rotation of the substrate during processing is chosen to achieve a desired process temperature profile that results in a highly uniform film thickness profile.

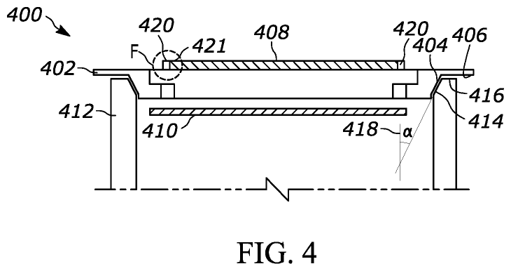

FIG. 4 illustrates a self-centering pocketless substrate carrier CVD system 400 of the present teaching with a substrate carrier 402 that has an edge 404 with a beveled geometry and a flat rim 406. The edge 404 of the substrate carrier 402 corresponds to a circular region at or near the outer perimeter of the substrate carrier 402. The edge 404 protrudes from the lower surface of the substrate carrier 402. A substrate 408 is centered on the upper surface of the substrate carrier 402 by post 420. The edge 404 of substrate 408 and post 420 contacts at contact interface 421, which is discussed further below.

A heating element 410 is located under the substrate carrier 402. The substrate 408, rim 406, and heating element 410 are all positioned in parallel. The substrate carrier 402 is positioned on a rotating support 412. The rotating support 412 has an edge 414 with a beveled geometry and a flat rim 416. The substrate carrier edge 404 and the rotating support edge 414 are proximate and parallel when the substrate carrier 402 is positioned on the rotating support 412. In some embodiments, the bevel geometry on the edge 414 of the rotating support 412 is formed at an angle α 418 with respect to the rotation axis of the rotating support 412. Similarly, the bevel geometry on the edge 404 of the substrate carrier 402 is set at an angle α 418 with respect to the center-axis of the carrier that runs normal to the upper surface of the substrate carrier that supports the substrate. In some embodiments, the angle α 418 is chosen such that tan(α)>f, where f is the coefficient of friction between the substrate carrier and rotation drum materials. The substrate carrier 402 does not have a pocket. Such substrate carriers are sometimes referred to as pocketless carriers where the posts 420 retain substrate 408 on substrate carrier 404 during operation.

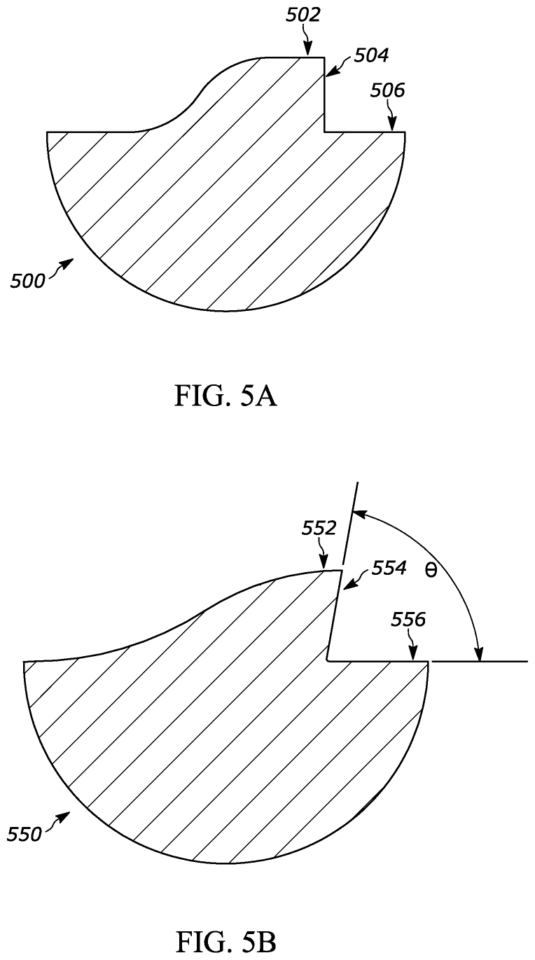

FIGS. 5A and 5B show details of post 420 and contact interface 421 as shown and described in connection with FIG. 4. See dotted circle F in FIG. 4. In FIG. 5A, item 500 shows the detail of substrate, substrate carrier, and post interface of substrate carrier 502 mentioned above. Item 502 is post 420 shown in FIG. 4. Item 506 is a portion of substrate carrier 402 on which substrate 408 rests. Item 504 is a wall of post 420 that forms the contact interface 421 where substrate 408 contacts post 420 (similar to item 502). The face of item 504, which interfaces with the substrate edge, can be flat or curved (for example, convex).

In FIG. 5B, surface 550 shows the detail of the substrate, the substrate carrier, and the post interface of the substrate carrier 402 described in connection with FIG. 4. Surface 552 is the post 420. In this embodiment, surface 554 is an undercut wall of the post 420 that forms contact interface 421. Surface 556 is a portion of the substrate carrier 402 on which the substrate 408 rests. Surface 554 and surface 556 form an angle Θ, which in various embodiments can range from about 80° to about 95°.

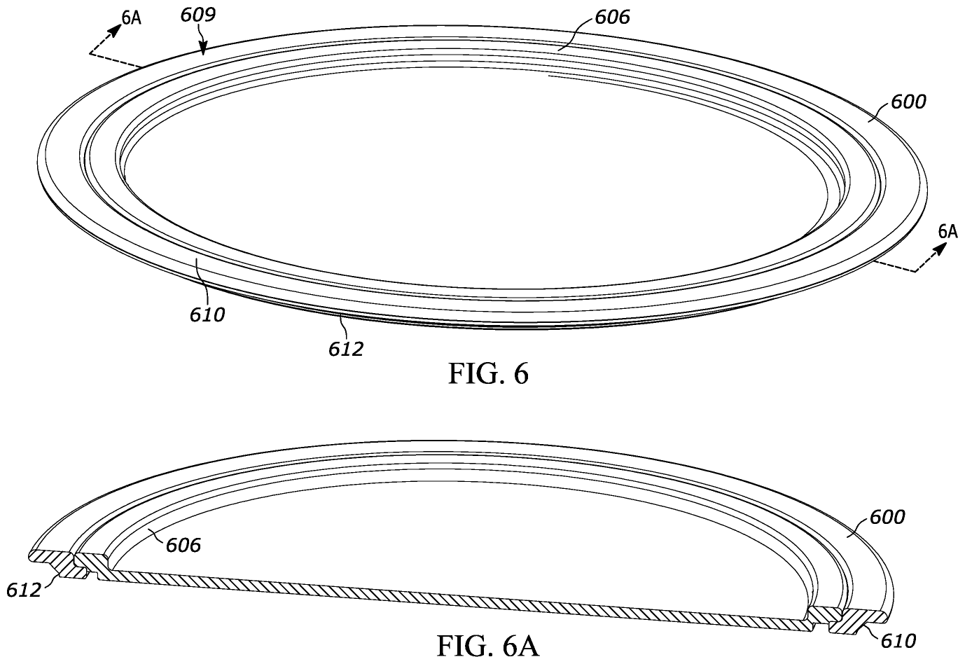

FIG. 6 shows an isometric view of a split substrate support ring (also called an open carrier or process tray) 600 according to the present teaching. The split substrate support ring 600 has edge 606 on which the outer edge of a substrate (not shown) rests. FIG. 6A is a cross-section of FIG. 6 through line A-A.

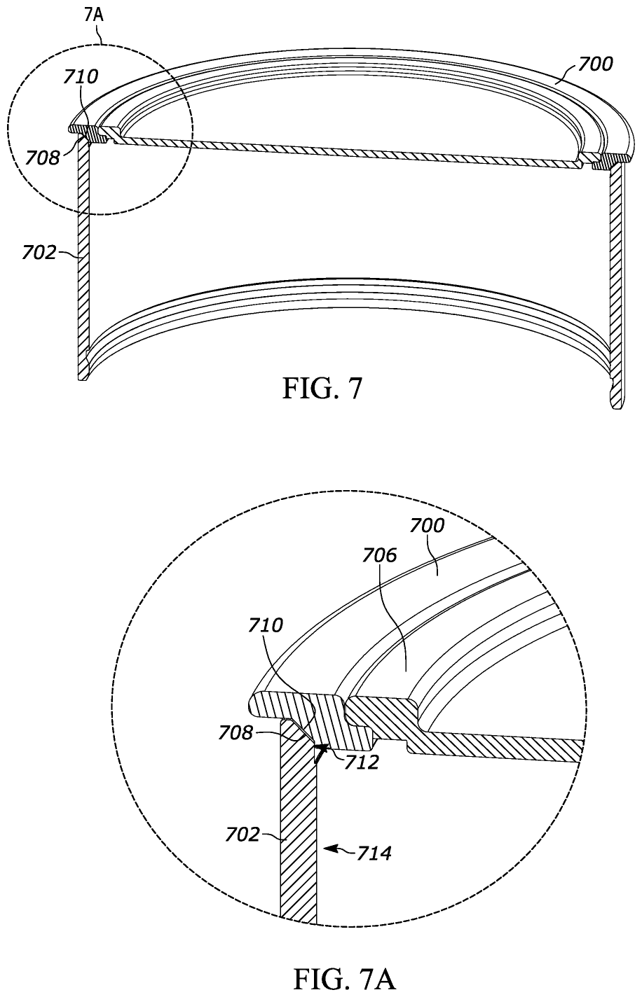

FIG. 7 illustrates a cross-section of the split substrate support ring of FIG. 6 mounted on a rotating support according to the present teaching. FIG. 7A shows a close-up view of circle A in FIG. 7. Referring to FIGS. 6, 6A, 7 and 7A, a cross-section of a split substrate support ring 600, 700 according to the present teaching is shown mounted on rotating support 702. The split substrate support ring 600, 700 has an edge 710 and an edge 712. Rotating support 702 has an inner edge 708 and an inner edge 714. The geometries of edge 710 of the split substrate support ring 700 and edge 708 of rotating support 702 are proximate and parallel. The geometries of edge 712 of split substrate support ring 700 and edge 714 of rotating support 702 are proximate and parallel when the split substrate support ring 700 is positioned on rotating support 702. The geometries are such that the split substrate support ring 700 rotates synchronously with rotating support 702 at all temperatures. Edge 712 can extend along edge 714 of rotating tube 702 from about 0.5 mm to about 7.5 mm.

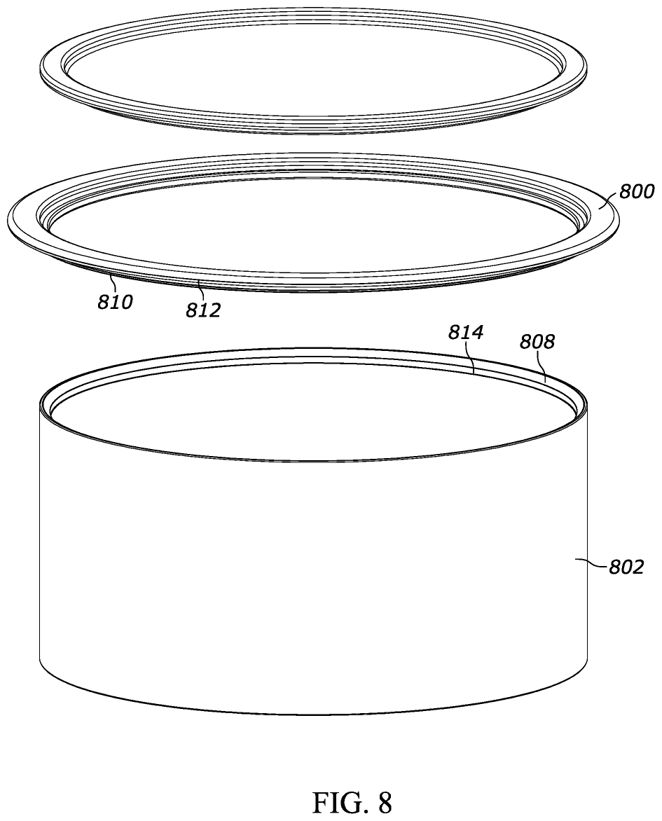

FIG. 8 illustrates an exploded view of the substrate support ring and rotating support described in connection with FIGS. 6, 6A, 7 and 7A according to the present teaching. Shown are the rotating support 802 with an edge 808 that is proximate and parallel to an edge 812 of the outer support ring 800 and an edge 814 that is proximate and parallel to an edge 810 of the outer support ring 800. The geometries of the edges 810, 812, 808, 814 of the support 802 and the outer support ring 800 are such that the support ring 800 rotates synchronously with the rotating tube 802 at all temperatures.

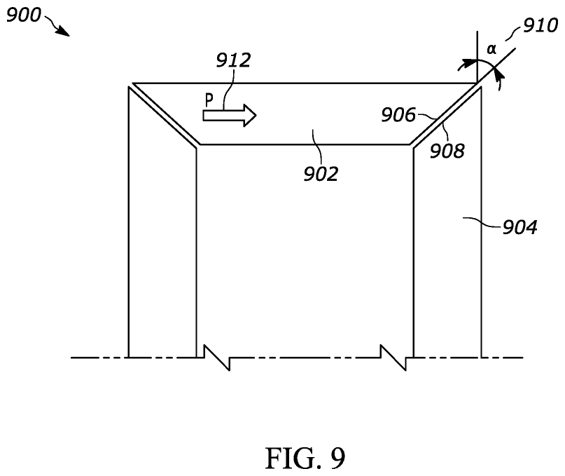

FIG. 9 illustrates a schematic side-view 900 of a self-centering substrate carrier 902 supported by a rotating support 904 according to the present teaching. FIG. 9 does not illustrate many of the features of the substrate carrier and rotating support of the present teaching, but rather is a simple schematic diagram intended to illustrate how a beveled edge 906 of the substrate carrier 902 rests on the matching beveled edge 908 of the rotating tube support 904 resulting in a conical interface. In some embodiments, the substrate carrier 902 is formed of graphite and coated with silicon carbide and the rotating tube support 904 is formed of quartz. In these embodiments, the coefficient of thermal expansion of the substrate carrier 902 is high, 4.5×10⁻⁶ l/° C., and the coefficient of thermal expansion of the rotating support tube 904 is low, 0.5×10⁻⁶ l/° C. The matching beveled edges 906, 908 make an angle ∝ 910 with respect to the vertical sidewall of the rotating support tube 904. In some embodiments, the cone angle ∝ 910 is selected to provide for the expansion of the substrate carrier without causing breakage or cracking of the rotating support 904 that results from their different coefficients of thermal expansion. In some embodiments, the cone angle ∝ 910 is chosen so that tan α>f, where f is the coefficient of friction, and where the room temperature coefficient of friction is 0.3, and the coefficient of friction for high temperature and low pressure is assumed to be one.

Any horizontal force 912 P in which

$$P > \frac{G ( 1 + f * tan ∝ )}{( tan ∝ - f )} ,$$

where G is the substrate carrier weight, will result in the substrate carrier lifting up in the vertical direction. The horizontal force 912 can be the result of a static force or a dynamic force unbalance. The force 912 due to the rotation of the substrate carrier 902 is proportional to the rotation rate squared, ω². Based on the expression,

$$P > \frac{G ( 1 + f * tan ∝ )}{( tan ∝ - f )} ,$$

the force P that can be tolerated without having the substrate carrier lifting up in the vertical direction goes up as α goes down and/or the coefficient of friction goes up.

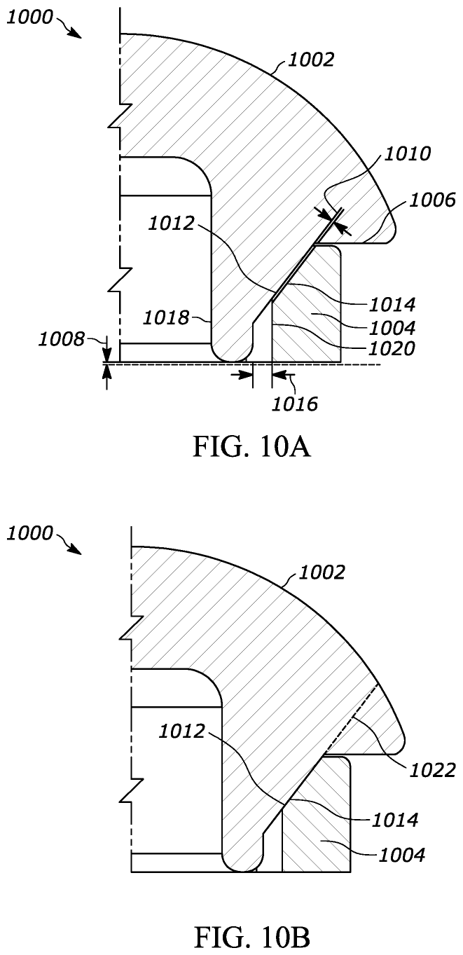

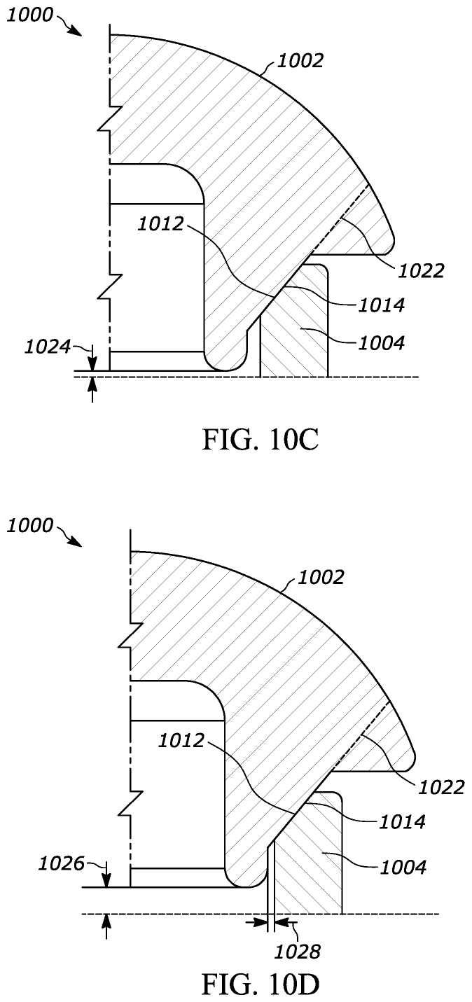

FIGS. 10A-D illustrate a series of expanded cross-sectional views 1000 of an embodiment of a self-centering substrate carrier 1002 and rotating support 1004 according to the present teaching at different operating temperatures. FIG. 10A is an expanded cross-sectional view 1000 of an embodiment of a self-centering substrate carrier 1002 and rotating support 1004 at room temperature. At room temperature, a flat bottom surface 1006 of the substrate carrier 1002 that rests on the top of the rotating support 1004 causes the bottom of the substrate carrier 1002 to sit at a position 1008 above a zero gap position. When the substrate carrier 1002 rests above a zero gap position, there is a small gap 1010 formed between the beveled edge 1012 of the substrate carrier 1002 and the beveled edge 1014 of the rotating support 1004. There is also a gap 1016 formed between the vertical rim 1018 of the substrate carrier 1002 and the edge 1020 of the rotating support 1004.

Referring to both FIGS. 10A and 10B is an expanded cross-sectional view 1000 of an embodiment of a self-centering substrate carrier 1002 and rotating support 1004 at 600° C. The geometry of the self-centering substrate carrier 1002 and rotating support 1004 is similar to the geometry shown in FIG. 10A at room temperature. However, the small gap 1010 (FIG. 10A) that was formed between the beveled edge 1012 of the substrate carrier 1002 and the beveled edge 1014 of the rotating support 1004 is now substantially zero at the 600° C. temperature. The beveled edges 1012, 1014 are in contact at position 1022.

Referring to all of FIGS. 10A, 10B, and 10C is an expanded cross-sectional view 1000 of an embodiment of a self-centering substrate carrier 1002 and rotating support 1004 at 750° C., which is a common operating temperature for CVD processes for fabrication multiple quantum well structures. The geometry of the self-centering substrate carrier 1002 and rotating support 1004 is similar to the geometry shown in FIG. 10B at 600° C. However, the substrate carrier 1002 has expanded as a result of the increased temperature, thereby causing the substrate carrier 1002 to vertically lift up, such that the substrate carrier is positioned at a distance 1024 above the original room temperature resting position 1008. The beveled edges 1012, 1014 remain in contact at position 1022.

FIG. 10D is an expanded cross-sectional view 1000 of an embodiment of a self-centering substrate carrier 1002 and rotating support 1004 at 1150° C., which is a common maximum operating temperature for CVD processes. The geometry of the self-centering substrate carrier 1002 and rotating support 1004 is similar to the geometry shown in FIG. 10C at 750° C. However, the substrate carrier 1002 has expanded further as a result of increasing the temperature to the maximum temperate, thereby causing the substrate carrier 1002 to vertically lift up further, such that the substrate carrier 1002 is positioned at a distance 1026 above the original room temperature resting position 1008. At 1150° C., the beveled edge 1014 of the rotating support 1004 remains in contact at position 1022 such that the gap 1010 (FIG. 10A) that was formed between the beveled edge 1012 of the substrate carrier 1002 and the beveled edge 1014 of the rotating support 1004 at room temperate is substantially zero. The room temperature gap 1016 (FIG. 10A) extending in the vertical direction has also reduced to a smaller gap 1028.

The various operating temperatures described in connection with FIGS. 10A-D are examples. Different substrate carriers and rotating supports according to the present teaching that are constructed with various materials and/or dimensions are, of course, capable of operating at different temperatures.

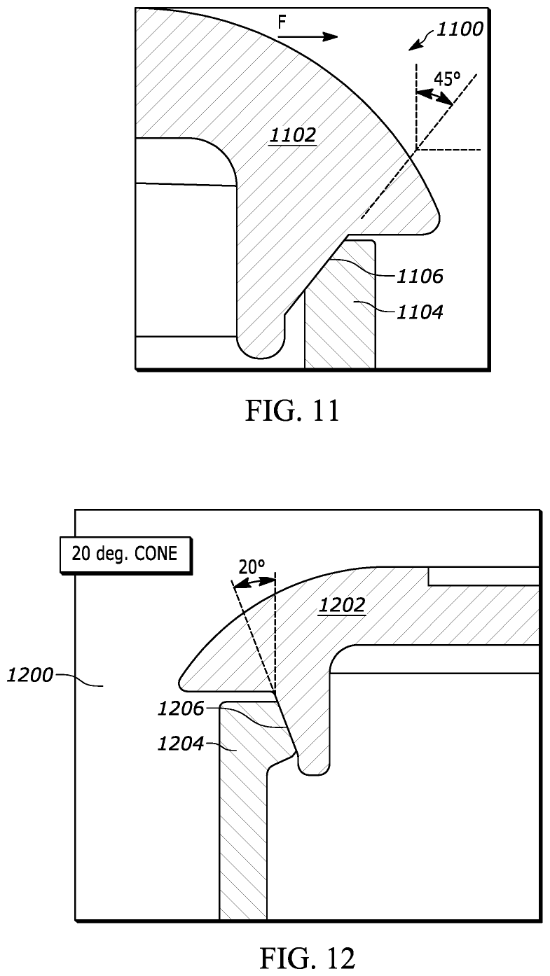

FIG. 11 illustrates an expanded cross-sectional view 1100 of an embodiment of a self-centering substrate carrier 1102 and rotating support 1104 that illustrates a conical interface 1106 according to the present teaching. The conical interface 1106 between the substrate carrier 1102 and the rotating support 1104 has an approximately 45-degree angle. The conical interface 1106 is designed to provide essentially a zero gap between the substrate carrier 1102 and the rotating support 1104 at the conical interface 1106 while also providing near perfect carrier centering along the rotation axis of the rotating support 1104. In addition, the conical interface 1106 is chosen to allow the substrate carrier 1102 to move vertically upward as the operating temperature increases causing thermal expansion and when the centripetal forces acting in the carrier plane are greater than a threshold value. The approximately 45 degree angle conical interface 1106 between the substrate carrier 1102 and the rotating support 1104 is chosen to facilitate vertical movement of the substrate carrier 1102 during thermal expansion when centripetal forces are greater than a threshold value.

However, a conical interface 1106 with an approximately 45-degree angle can result in substrate carrier 1102 tilting during thermal expansion and vertical movement, particularly when experiencing a centripetal force acting in the carrier plane that is over the threshold value.

One aspect of the present teaching is the realization that the undesirable tilt that results from thermal expansion and vertical movement of the substrate carrier during processing temperatures can be mitigated by reducing the centripetal force experienced by the substrate carrier 1102 to below a threshold centripetal force acting in the carrier plane. As described herein, the centripetal force is proportional to the square of the rotation rate. Therefore, one aspect of the present teaching is to reduce the rotation rate of the substrate carrier 1102 to below a threshold rotation rate that results in centripetal force below a threshold centripetal force.

For example, in one particular embodiment of the substrate carrier 1102 and rotating support 1104 with a conical interface 1106 between the substrate carrier 1102 and the rotating support 1104 at approximately a 45 degree angle, the rotation rate needs to be kept to less than 400 rpm at temperatures below 600° C. so that the centripetal force acting in the substrate carrier plane experienced by the substrate carrier 1102 is below the threshold centripetal force which result in vertical movement of the substrate carrier 1102 and physical tilt. It was determined that at temperatures greater than 600° C., rotation rates greater than 400 rpm can be utilized.

Another aspect of the present teaching is the realization that the undesirable tilt that results from vertical movement of the substrate carrier 1102 during increased processing temperatures and that results from rotation at rotation rates that cause centripetal forces acting in the substrate carrier 1102 plane to be greater than the threshold centripetal force, can be mitigated by changing the angle of the conical interface 1100 so that the substrate carrier 1102 self-locks in a way that substantially prevents vertical motion of the substrate carrier 1102. In this aspect of the present teaching, the conical interface 1100 is designed to be at a self-locking cone angle that substantially eliminates vertical motion of the substrate carrier 1102 at operating temperatures. In addition, in this aspect of the present teaching, the substrate carrier 1102 and the rotating support 1104 are formed of materials with similar coefficients of thermal expansion so that both the substrate carrier 1102 and the rotating support 1104 expand at approximately the same rate, thereby reducing the probability of cracking the substrate carrier 1104.

FIG. 12 illustrates an expanded cross-sectional view 1200 of an embodiment of a self-centering substrate carrier 1202 and rotating support 1204 with a conical interface 1206 that has a self-locking angle. The conical interface 1206 between the substrate carrier 1202 and the rotating support 1204 is configured at a self-locking angle that substantially eliminates physical tilting of the substrate carrier 1202 during operation according to the present teaching. This self-locking angle has been determined to be approximately 20 degrees for some specific embodiments of the conical interface 1206 between the substrate carrier 1202 and the rotating support 1204. In other specific embodiments, self-locking angle has been determined to be in the range of 18-22 degrees. To prevent damage of one or both of the substrate carrier 1202 and the rotating support 1204 during thermal stress, these components should be made of materials with similar coefficients of thermal expansion. By similar coefficients of thermal expansion, we mean within 5%.

The acceptable difference in coefficients of thermal expansion of the materials used to form the substrate carrier 1202 and the rotating support 1204 depends on several factors, such as the operating temperature range, the particular material properties, the particular geometry of the components, and the rotation rate. In one particular embodiment, the substrate carrier 1202 is formed of silicon carbide coated graphite and the rotating support 1204 is formed of either tantalum-carbide-coated graphite or molybdenum. Both computer simulations and experiments have demonstrated that when the rotating support 1204 is formed of both graphite and molybdenum materials essentially the same temperate profile can be achieved as the substrate carrier 1202. However, both computer simulations and experiments also show that during heating, the substrate carrier 1202 expands more than the rotating support 1204 if the top plane of the rotating support 1204 is physically restrained by the much cooler bottom plane of the rotating support 1204. The heating results in additional stress in the rotating support 1204. Consequently, it is desirable to have a conical interface configuration at a self-locking angle where there is a small initial gap between the substrate carrier 1202 and the rotating support 1204.

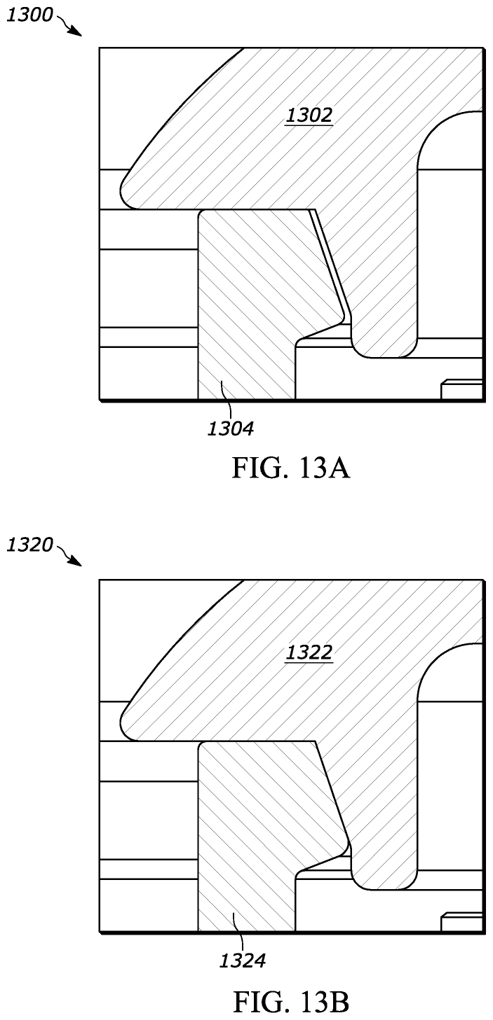

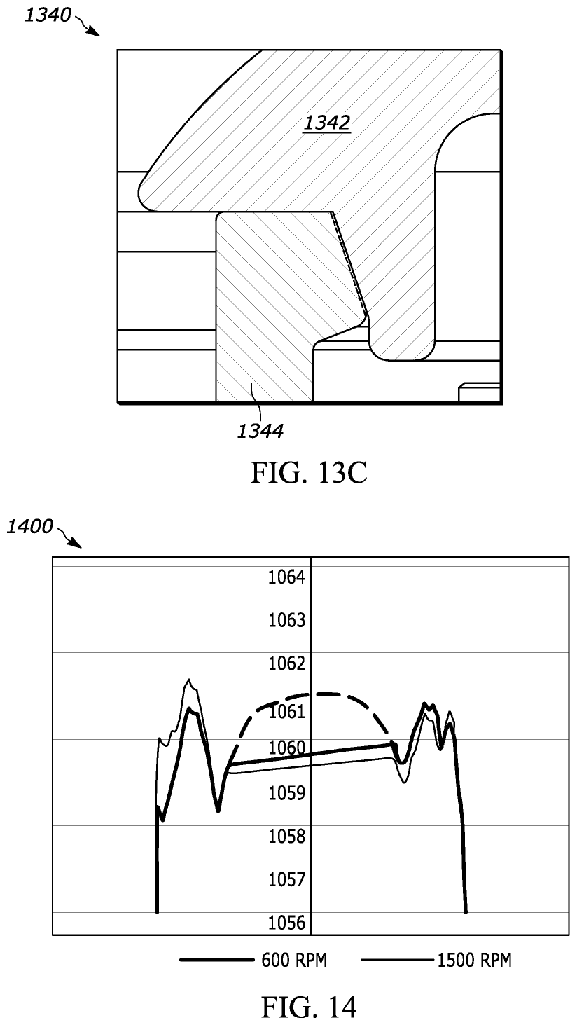

FIGS. 13A-C illustrate expanded-views of an embodiment of a conical interface between the substrate carrier and the rotating support that is configured at a self-locking angle that substantially eliminates physical tilting of the substrate carrier during operation according to the present teaching at various temperatures.

FIG. 13A illustrates an expanded cross-sectional view 1300 of an embodiment of a conical interface between the substrate carrier 1302 and the rotating support 1304 that is configured at a self-locking angle according to the present teaching with a small initial gap at room temperature. In this embodiment of the conical interface, the small initial gap in the conical interface between the substrate carrier 1302 and the rotating support 1304 is about 0.18 mm for a configuration with a substrate carrier 1302 comprising graphite material and a rotating support 1304 comprising graphite material. For a configuration with a substrate carrier 1302 comprising graphite and a rotating support 1304 comprising molybdenum, the small initial gap in the conical interface between the substrate carrier 1302 and the rotating support 1304 is about 0.10 mm.

FIG. 13B illustrates an expanded cross-sectional view 1320 of an embodiment of a conical interface between the substrate carrier 1322 and the rotating support 1324 that is configured at a self-locking angle according to the present teaching with a substantially zero initial gap at about 750 degrees C. The 750-degree C. processing temperature is a temperature that is often used to grow multiple quantum well structures for semiconductor lasers. In this embodiment, the initial gap in the conical interface between the substrate carrier 1322 and the rotating support 1324 is substantially zero but still finite for a substrate carrier 1322 comprising a graphite material and a rotating support 1324 comprising graphite material. For this configuration, the initial gap is about 0.05 mm. In a different embodiment of the conical interface, with a rotating support 1324 comprising a molybdenum material and a substrate carrier 1322 comprising a graphite material, the initial gap is still small, but has increased to about 0.13 mm.

FIG. 13C illustrates an expanded cross-sectional view 1340 of an embodiment of a conical interface between the substrate carrier 1342 and the rotating support 1344 that is configured at a self-locking angle according to the present teaching with a substantially zero initial gap at about 1100 degrees C. The 1100 degrees C. processing temperature is a temperature that is often used to grow GaN structures for blue semiconductor lasers. In this embodiment of the conical interface, the initial gap in the conical interface between the substrate carrier 1342 and the rotating support 1344 is substantially zero and there is a force exerted on the rotating support 1344 from the expanding substrate carrier 1342. For a graphite substrate carrier 1342 and a graphite rotating support 1344, there is an initial gap of about −0.01 mm at 1100 degrees C., in other words a negative gap, meaning that the substrate carrier 1342 moves the rotating support 1344 away from its resting position about 0.01 mm. In a different embodiment of the conical interface, with a molybdenum rotating support 1344 and a graphite substrate carrier 1342 the initial gap is small, about 0.15 mm.

FIG. 14 illustrates a graph 1400 of temperature as a function of distance across a substrate carrier for a rotating disk reactor configuration with a conical interface between the substrate carrier and the rotating support that is configured at a self-locking angle according to the present teaching. The conical interface was configured with a self-locking angle of 20 degrees and with an initial gap of about 0.4 mm. The rotating support was formed of graphite without any additional coatings. Thickness of the rotating support was about 5 mm. The graph 1400 illustrates that at a temperature of 1060 degrees C., the temperature uniformity is +/−1 degrees C.

The self-locking carrier-to-support interface according to the present teaching can be used with both split substrate carriers and single-piece substrate carriers. In general, split substrate carrier configurations are desirable when substrates being processed experience large ranges of curvature due to temperature changes. For example, during MOCVD processing, such as GaN on Silicon MOCVD processing, the substrate experiences a large range of curvature changes as the processing temperature cycles. These curvature changes range from a concave (bowl shaped) curvature to a convex (inverted bowl shaped) curvature. For example, for relatively large diameter substrates, such as 300 mm diameter substrates, the curvature can go from about 300 microns of concave curvature to about 500 microns of convex curvature during MOCVD processing.

Some state-of-the art MOCVD systems, such as those manufactured by Veeco Instruments Inc., the assignee of the present application, are configured to locally change the temperature of the substrate carrier so as to maintain temperature uniformity across the substrate being processed while the substrate bows from a convex shape to concave shape during MOCVD processing. In some of these systems, the substrate heater is adjusted so that the carrier/pocket temperature profile maintains a uniform temperature profile on the growth surface of the substrate while the substrate bows during MOCVD processing. For example, when the substrate is bowed in a convex shape, the center region of the substrate moves away from the pocket floor of the substrate carrier and consequently, the temperature on the growth surface of the substrate reduces in the center region. The heating system in the MOCVD reactor then compensates by locally increasing the temperature of the substrate carrier in the corresponding area in the center region of the carrier center. Similarly, when the substrate is bowed in a concave shape during MOCVD processing, the center of the substrate moves towards the pocket floor of the substrate carrier and consequently, the temperature in the center region of the substrate locally increases. The heating system in the MOCVD reactor then compensates by locally reducing the temperature in the center region area in the carrier center.

The local temperature changes in the center region of the substrate carrier cause an undesirable temperature gradient from the center-to-edge of the pocket in the substrate carrier, which results in a tensile hoop stress at the edge of the substrate carrier. In addition, the resulting temperature gradient causes a radiative heat loss on the edge of the substrate carrier. In some CVD reactor systems, the edge is a ledge where a robot end effector picks up the substrate carrier for automated loading and unloading. This radiative heat loss further increases tensile hoop stresses at the edge of the substrate carrier. The resulting high tensile hoop stresses at the edge of the substrate carrier can cause the substrate carrier to weaken enough to affect the structural integrity of the substrate carrier.

One feature of the present teaching is the substrate carrier can be configured in a split substrate carrier configuration as described in connection with FIGS. 6, 6A, 7, 7A, and 8 where the substrate carrier comprises a first and second section. The split substrate carrier configuration mechanically decouples a first section of the carrier from a second section of the carrier so that the tensile hoop stresses at the edge of the substrate carrier, which results from localized heating and from the temperature gradient that causes the radiative heating loss, are reduced. Such a configuration is effective at reducing tensile hoop stresses at the edge of the substrate carrier enough to keep the maximum stresses lower than acceptable thresholds for many MOCVD systems.

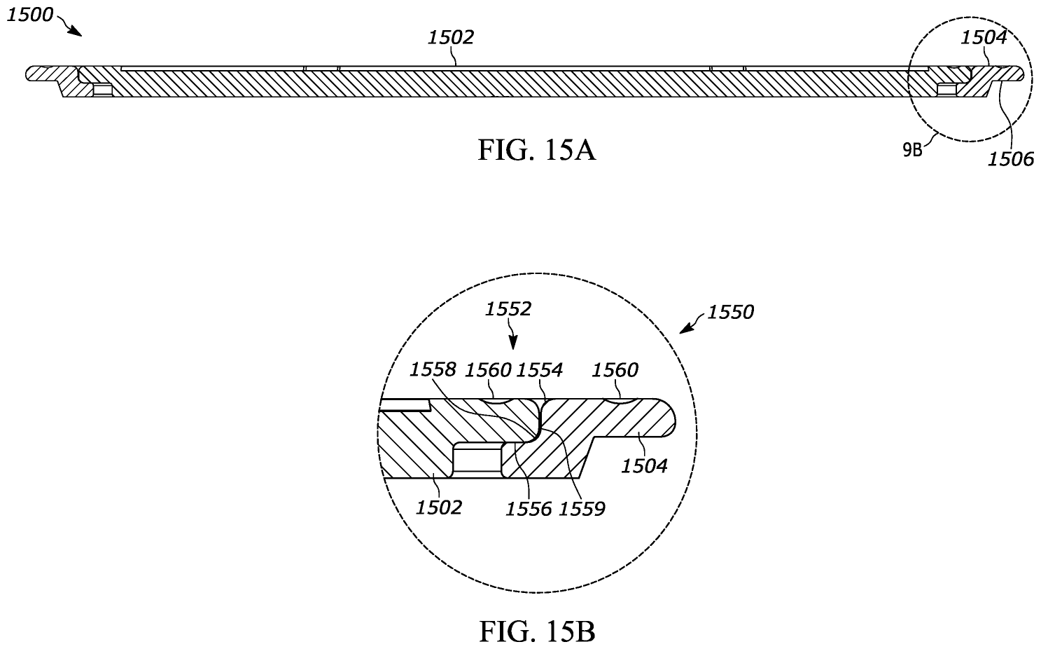

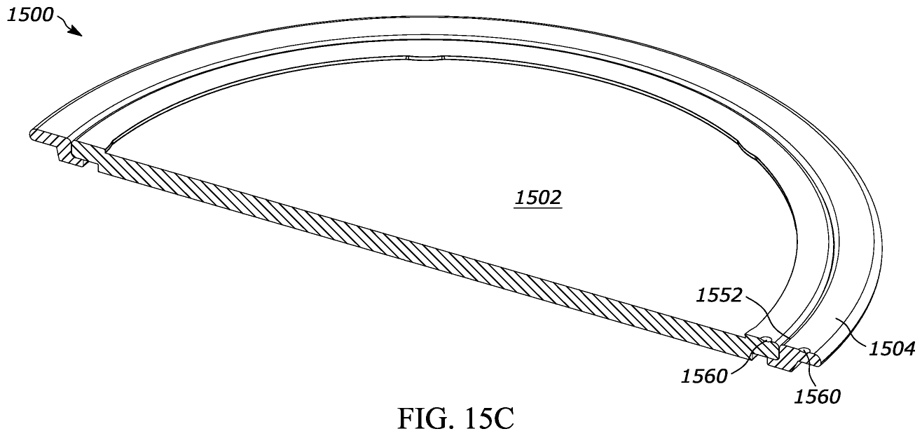

FIG. 15A illustrates a cross-sectional view of a self-centering split substrate carrier 1500 according to the present teaching. The split substrate carrier 1500 includes a first section 1502 that is circularly shaped like a central “puck” that is centrally located. In addition, the split substrate carrier 1500 includes a second section 1504 that is shaped like an outer edge ring that is positioned around the circularly-shaped first section 1502. The second section 1504 that is shaped like an outer edge ring is configured to interface with an edge drive rotation mechanism. In some embodiments, the edge drive rotation mechanism is a rotating support, such as a rotating tube, rotating drum, or rotating disk. In some embodiments, the second section 1504 is shaped like an outer edge ring and is configured so that a transfer robot can pick up the substrate carrier 1500 at an outer edge 1506. The first 1502 and the second sections 1504 can be made of various materials, such as SiC coated graphite, TaC coated graphite, CVD SiC, molybdenum, titanium zirconium molybdenum (TZM). In some embodiments, the first 1502 and the second sections 1504 are made of the same material or are each made with a different material that has substantially the same coefficient of thermal expansion. In other embodiments, the first 1502 and the second sections 1504 are each made of materials with different coefficient of thermal expansions.

FIG. 15B illustrates an expanded cross-sectional view at one edge 1550 of the self-centering split substrate carrier 1500 according to the present teaching that was described in connection with FIG. 15A. Referring also to FIG. 15A, the expanded cross-sectional view at one edge 1550 shows details of the interface 1552 between the first section 1502 that is circularly shaped and centrally located and the second section 1504 that is shaped like an outer edge ring around the circularly-shaped first section 1502. In some embodiments, there is a radial clearance 1554 at the interface 1552 between the first 1502 and the second sections 1504. This radial clearance 1554 is dimensioned to allow for the relative thermal expansion of the first 1502 and the second sections 1504, which prevents stress from being transferred between the first 1502 and the second sections 1504. In some embodiments, the radial clearance 1554 is in the range of 100-500 microns. In one particular embodiment, the radial clearance 1554 is about 250 microns.

In some embodiments, the second section 1504 shaped like an outer edge ring around the circularly-shaped first section 1502 includes an inner ledge 1556 having a flat portion where the circularly-shaped first section 1502 rests. In one particular embodiment, the inner ledge 1556 is between 2.5 and 3.5 mm long. For example, the inner ledge 1556 is about 2.75 mm long in one particular embodiment. In one embodiment, the outer bottom surface 1558 of the first section 1502 has an outer radius that is smaller than a radius of the corresponding mating surface 1559 of the second section 1504 shaped like an outer edge ring.

One feature of the present teaching is that the circularly-shaped first section 1502 and the second section 1504 shaped like an outer edge ring can include identifying features that can be used to angularly align the first section 1502 relative to the second section 1504 in a repeatable manner. In the embodiment shown in FIGS. 15A and 15B, a plurality of shallow dimples 1560 are machined into the top surface of both the first 1502 and second sections 1504 proximate to the interface 1552 between the first 1502 and second sections 1504.

FIG. 15C illustrates a top perspective view of the self-centering split substrate carrier 1500 described in connection with FIG. 15A. The top perspective view shows the first section 1502 that is circularly shaped and that is centrally located. In addition, the split substrate carrier 1500 includes a second section 1504 that is shaped like an outer edge ring and that is positioned around the circularly-shaped first section 1502. The top perspective view also shows the interface 1552 between the first section 1502 and the second section 1504. Dimples 1560 are machined into the top surface of the first 1502 and second sections 1504 proximate to the interface 1552 are also shown.

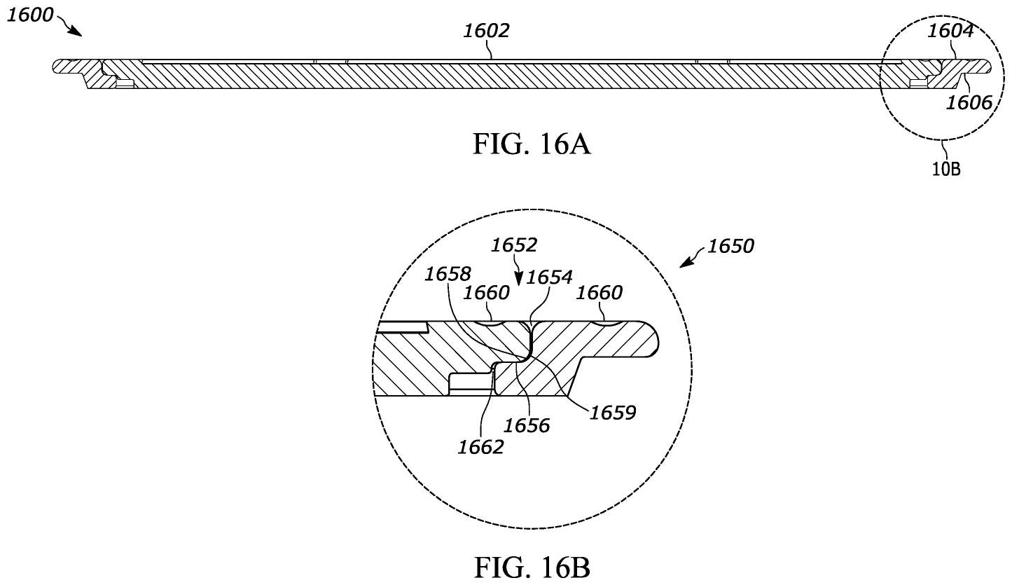

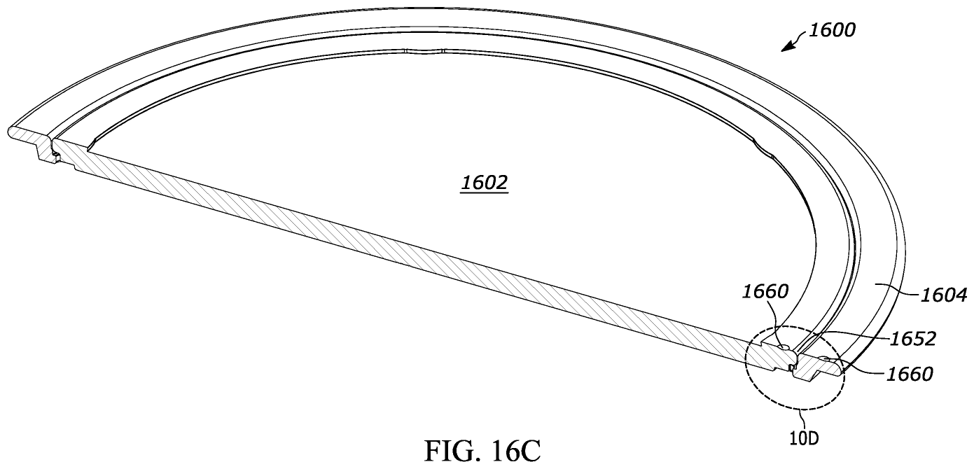

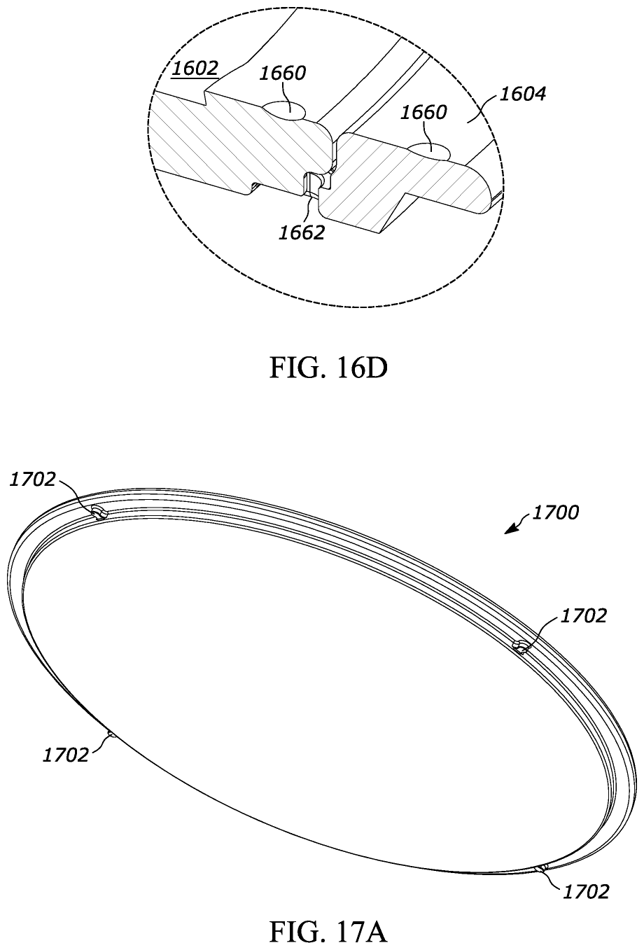

FIG. 16A illustrates a cross-sectional view of another self-centering split substrate carrier 1600 according to the present teaching. The self-centering split substrate carrier 1600 is similar to the self-centering split substrate carrier 1500 that is described in connection with FIGS. 15A and 15B. The split substrate carrier 1600 includes a first section 1602 that is circularly shaped like a central “puck” that is centrally located. In addition, the split substrate carrier 1600 includes a second section 1604 that is shaped like an outer edge ring that is positioned around the circularly-shaped first section 1602. The second section 1604 is shaped like an outer edge ring and is configured to interface with an edge of an edge-drive rotation mechanism, such as a rotating support, which can be a tube or drum. In some embodiments, the second section 1604 shaped like an outer edge ring is configured so that a transfer robot can pick up the substrate carrier 1600 at an outer ledge 1606.

As described in connection with FIGS. 15A and 15B, the first 1602 and the second sections 1604 can be made of various materials. The first 1602 and the second sections 1604 can each be made of one or more materials that have substantially the same coefficient of thermal expansion. Alternatively, first 1602 and the second sections 1604 can each be made of materials that have a different coefficient of thermal expansion.

FIG. 16B illustrates an expanded cross-sectional view at one edge 1650 of the self-centering split substrate carrier 1600 according to the present teaching that was described in connection with FIG. 16A. The expanded cross-sectional view at one edge 1650 shows details of the interface 1652 between the first section 1602 that is circularly shaped and centrally located and the second section 1604 that is shaped like an outer edge ring around the circularly-shaped first section 1652. In some embodiments, there is a radial clearance 1654 at the interface 1652 between the first 1602 and the second sections 1604. This radial clearance 1654 is dimensioned to allow for the relative thermal expansion of the first 1602 and the second sections 1604. This relative thermal expansion prevents stress from being transferred between the first 1602 and the second sections 1604. In some embodiments, the radial clearance 1654 is in the range of 100-500 microns. In one particular embodiment, the radial clearance 1654 is about 250 microns.

As described in connection with FIG. 15B, in some embodiments, the second section 1604 shaped like an outer edge ring around the circularly-shaped first section 1602 includes an inner ledge 1656 having a flat portion where the circularly-shaped first section 1602 rests on the inner ledge 1656. For example, the inner ledge 1656 can range from about 2.5 to about 3.5 mm long in some embodiments. In one embodiment, the outer bottom surface 1658 of the first section 1602 has an outer radius that is smaller than a radius of the corresponding mating surface 1659 of the second section 1604 shaped like an outer edge ring.

Also, as described in connection with FIG. 15B, in some embodiments, the circularly-shaped first section 1602 and the second section 1604 shaped like an outer edge ring can include identifying features that can be used to align the first 1602 and second section 1604 angular in a repeatable manner. In the embodiment shown in FIGS. 16A and 16B, shallow dimples 1660 are machined into the top surface of the first 1602 and second sections 1604 proximate to the interface 1652.

The self-centering split substrate carrier 1600 also includes a gap 1662 between the bottom of the circularly-shaped first section 1602 and the second section 1604 shaped like an outer edge ring. Either or both of the circularly-shaped first section 1602 and the second section 1604 shaped like an outer edge ring can be formed so that the gap 1662 is present when the first section 1602 is positioned on the second section 1604.

This gap 1662 effectively creates a more labyrinthine gas flow path between the first section 1602 and the second section 1604 that reduces or minimizes gas diffusion from the reaction space proximate to the top surfaces of the substrate carrier 1600 and the heater volume proximate to the bottom surfaces of substrate carrier 1600.

FIG. 16C illustrates a top perspective view of the self-centering split substrate carrier 1600 described in connection with FIG. 16A. Similar to the top perspective view of self-centering split substrate carrier 1500 described in connection with FIG. 15C, the top perspective view shows the first section 1602 that is circularly shaped and that is centrally located and the second section 1604 that is shaped like an outer edge ring and that is positioned around the circularly-shaped first section 1602. Also, the interface 1652 between the first section 1602 and the second section 1604 is shown. Dimples 1660 are machined into the top surface of the first 1602 and second sections 1604 proximate to the interface 1652 are also shown.

FIG. 16D illustrates an expanded top perspective view of the self-centering split substrate carrier described in connection with FIGS. 16A and 16B. The expanded top perspective view additional shows the gap 1662 between the bottom of the circularly-shaped first section 1602 and the second section 1604 shaped like an outer edge ring.

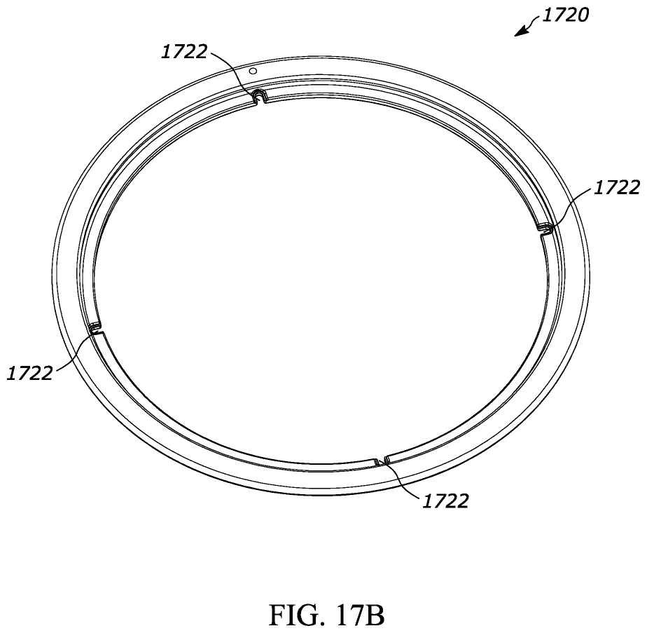

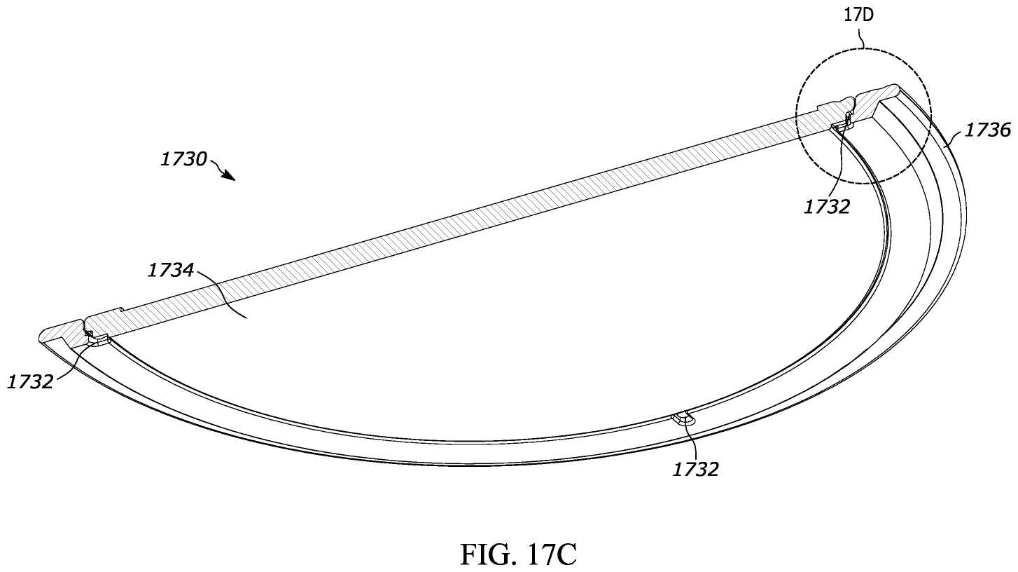

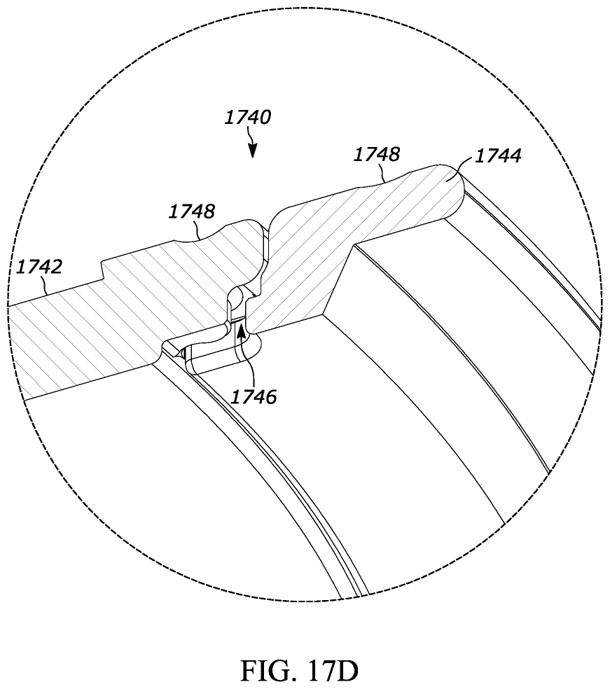

FIGS. 17A-D illustrates an embodiment of the self-centering split substrate carrier 1700 described in connection with FIGS. 16A-D that includes alignment features. The features of FIGS. 17A-D can also be used with the configuration shown in FIGS. 15A-D. FIG. 17A illustrates a perspective view of a first section of the self-centering split substrate carrier 1700 that is circularly shaped like a central “puck” and configured to be centrally located in the substrate carrier 1700 with alignment features according to the present teaching. The perspective view of the first section of the self-centering split substrate carrier shows a plurality of pins 1702 that is used for alignment. In the specific embodiment shown, there are four pins 1702 used for alignment. More generally, the plurality of pins 1702 according to the present teaching are boss structures, which are any type of protruding features on the first section of a self-centering split substrate carrier 1700 that are dimensioned to locate the first section of a self-centering split substrate carrier 1700 with a corresponding aperture or slot on the second section 1720 (FIG. 17B) of the substrate carrier 1700.

FIG. 17B illustrates a perspective view of a second section 1720 of the self-centering split substrate carrier that is shaped like an outer edge ring with alignment features according to the present teaching. The second section 1720 is configured so that the outer edge ring interfaces with an edge of a drive rotation mechanism, such as the rotating tube described herein. In addition, the second section 1720 includes plurality of slots 1722 that interface with the pins (bosses) 1702 that align and center the first section 1700 of a self-centering split substrate carrier relative to the second section 1720 of the self-centering split substrate carrier. One feature of using the combination of the plurality of pins (bosses) 1702 and the plurality of slots 1722 is that they center concentrically while allowing for radial expansion.

FIG. 17C illustrates a perspective cross-sectional view of a self-centering split substrate carrier 1730 with alignment features according to the present teaching. Referring to FIGS. 17A-17C, in the embodiment shown, the alignment features are a plurality of pins 1732 like those describe in connection with FIGS. 17B and 17C that are used to align and center a first section 1734 of the self-centering split substrate carrier relative to the second section 1736 of the self-centering split substrate carrier.

FIG. 17D illustrates an expanded perspective cross-sectional view of an interface 1740 between a circularly shaped first section 1742 and a second section 1744 shaped like an outer edge ring of a self-centering split substrate carrier according to the present teaching. The expanded perspective cross-sectional view shows the shallow dimples 1748 machined into the top surface of the first 1742 and second section 1744 proximate to the interface 1740. The expanded perspective cross-sectional view also shows a gap 1746 between the bottom of the circularly-shaped first section 1742 and the second section 1744 shaped like an outer edge ring. This gap 1746 effectively creates a more labyrinthine gas flow path between the first section 1742 and the second section 1744 that reduces gas diffusion from the reaction space proximate to the top surfaces of the substrate carrier and the heater volume proximate to the bottom surfaces of substrate carrier.

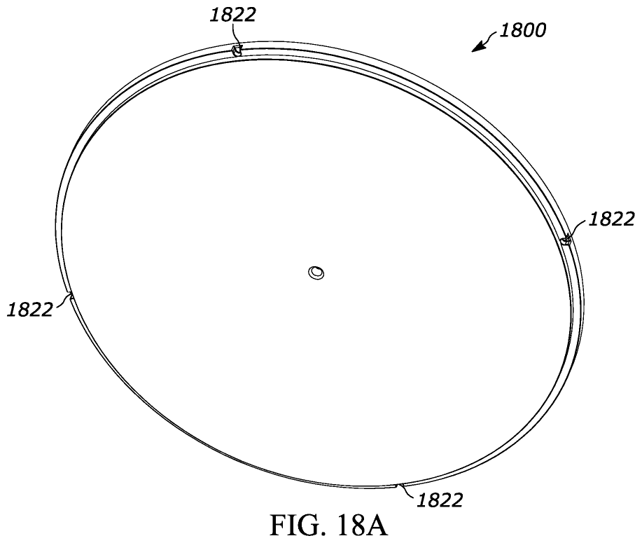

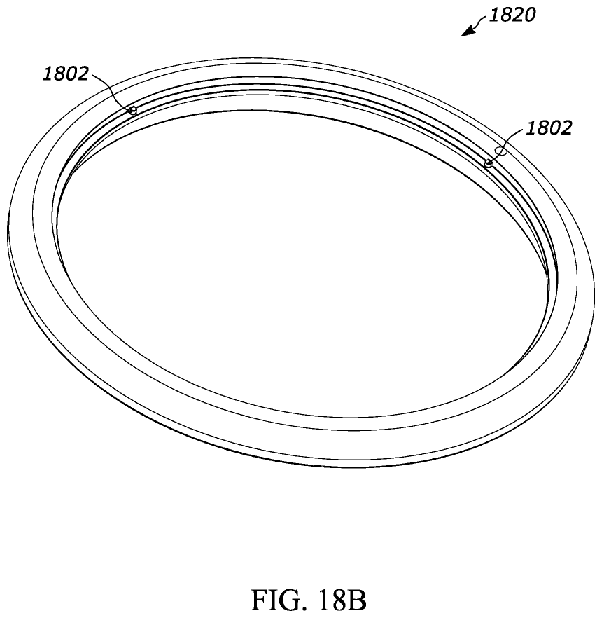

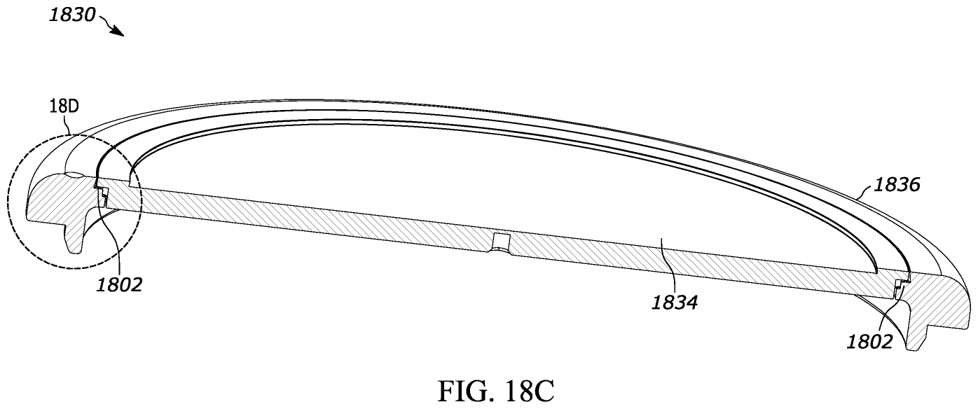

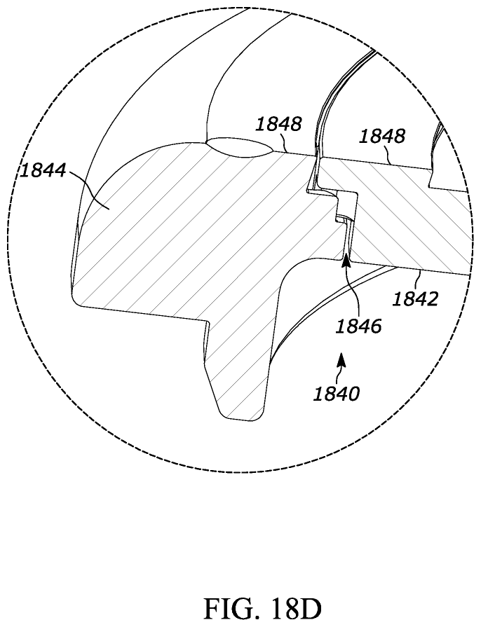

FIGS. 18A-D illustrates another embodiment of the self-centering split substrate carrier 1800 described in connection with FIGS. 16A-D that includes alignment features. The features of FIGS. 18A-D can also be used with the configuration shown in FIGS. 15A-D. FIG. 18A illustrates a perspective view of a first section of another self-centering split substrate carrier 1800 that is circularly shaped like a central “puck” and configured to be centrally located in a second section of the substrate carrier. The first section of the self-centering split substrate carrier 1800 includes a recessed area for receiving one or more substrates for processing. The first section of the self-centering split substrate carrier 1800 has alignment features according to the present teaching. The perspective view of the first section of the self-centering split substrate carrier 1800 shows a plurality of apertures 1822 that are positioned at various locations around the outer perimeter of the substrate carrier 1800.

FIG. 18B illustrates a perspective view of a second section 1820 of the other self-centering split substrate carrier that is configured as a flange. The second section 1820 includes a plurality of pins 1802 positioned around an inner surface. Respective ones of the plurality of apertures 1822 in the first section of the self-centering split substrate carrier 1800 are configured to receive respective ones of a plurality of pins 1802 positioned around the inner surface of the second section 1820 so as to improve alignment of the first and the second section of the self-centering split substrate carrier 1800, 1820. The second section 1820 is configured so that the outer edge ring interfaces with an edge of a drive rotation mechanism, such as the rotating tube described herein, so that the drive rotation mechanism controls the rotation of the substrate carrier.

In the specific embodiment shown, there are four pins 1802 used for alignment. However, only two of the four pins 1802 are shown in FIG. 18B. It should be understood that any number of pins 1802 can be used. More generally, the plurality of pins 1802 in the second section 1820 of the self-centering split substrate carrier are boss structures, which can be any type of protruding features on the second section 1820 of the self-centering split substrate carrier. These boss structures are dimensioned to interface with corresponding ones of the plurality of apertures 1822 that are positioned at various locations around the outer perimeter of the substrate carrier 1800.

FIG. 18C illustrates a perspective cross-sectional view of a self-centering split substrate carrier 1830 with alignment features according to the present teaching, which are described in connection with FIGS. 18A and 18B. Referring to FIGS. 18-18C, in the embodiment shown, the alignment features are a plurality of pins 1802 like those describe in connection with FIG. 18B, which are used to align and center a first section of the self-centering split substrate carrier 1800 relative to the second section of the self-centering split substrate carrier 1820.

One aspect of the self-centering split substrate carrier of the present teaching is the realization that configuring the first section of the self-centering split substrate carrier 1800 to have a plurality of apertures 1822 which receives the plurality of pins 1802 results in a flatter bottom surface when supporting the substrate in the pocket 1834 of the first section of the self-centering split substrate carrier 1800 during processing. The pocket 1834 is an example of an embodiment of a recessed area in the carrier for receiving a substrate for processing. This flatter bottom surface results in more a uniform temperature distribution across the wafer during processing, which results in high process yields.

FIG. 18D illustrates an expanded perspective cross-sectional view of an interface 1840 between a circularly shaped first section 1842 and a second section 1844 shaped like an outer edge ring of a self-centering split substrate carrier according to the present teaching. The expanded perspective cross-sectional view shows the shallow dimples 1848 machined into the top surface of the first 1842 and second section 1844 proximate to the interface 1840. The expanded perspective cross-sectional view also shows a gap 1846 between the bottom of the circularly-shaped first section 1842 and the second section 1844 shaped like an outer edge ring. This gap 1846 effectively creates a more labyrinthine gas flow path between the first section 1842 and the second section 1844 that reduces gas diffusion from the reaction space proximate to the top surfaces of the substrate carrier and the heater volume proximate to the bottom surfaces of substrate carrier.

Thus, one aspect of the present teaching is a split substrate carrier that supports a semiconductor substrate in a chemical vapor deposition system that includes a support having a beveled inner top surface. The support can be a rotating tube with a beveled edge as described herein. A first section is circularly shaped and includes a top surface having a recessed area for receiving at least one substrate for chemical vapor deposition processing. A second section is shaped like an outer edge ring and is positioned around the circularly-shaped first section to form an outer edge ring that is configured to interface with an edge drive rotating mechanism, such as a rotating tube as described herein. A radial clearance between the first and second sections can be in the range of 100-500 microns.

The second section includes a bottom surface having a beveled edge that forms a conical interface with the beveled inner top surface of the support. In some embodiments, the second section includes an inner ledge having a flat portion where the circularly-shaped first section rests. Also, in one embodiment, the second section comprises an outer ledge.

In one embodiment, an outer bottom surface of the first section has an outer radius that is smaller than a radius of a corresponding mating surface of the second section. Also, in one embodiment, an outer bottom surface of the first section has an outer radius that is selected to improve centering of the first section on top of the second section.

In one embodiment, a top surface of each of the first and second sections comprise a plurality of dimples that are positioned proximate to an interface between the first and second sections, where the plurality of dimples are configured to provide angular alignment of the first section relative to the second section. Also, in one embodiment, the first section comprises a plurality of boss structures and the second section comprises a plurality of corresponding apertures, where a respective one of the plurality of boss structures is positioned to interface with a respective one of the plurality of apertures so that the first and second sections are centered concentrically while allowing for radial thermal expansion of the first section relative to the second section.

Also, in one embodiment, the first and second sections are configured to form a gap between the first section and the second section, where the gap is dimensioned to create a labyrinthine gas flow path between the first section and the second section that reduces gas diffusion from a reaction space proximate to the top surfaces of the substrate carrier and a heater volume proximate to the bottom surfaces of substrate carrier.

In various embodiments, the first and the second sections can be formed of materials that have the same coefficient of thermal expansion or different coefficients of thermal expansion. At least one of the first and the second sections can be formed of at least one of SiC coated graphite and TaC coated graphite. At least one of the first and the second sections can also be formed of TaC coated graphite or molybdenum. Also, at least one of the first and the second sections can be formed of titanium zirconium molybdenum (TZM).

A method of manufacturing a substrate carrier that supports at least one semiconductor substrate on a top surface of the substrate carrier in a chemical vapor deposition system at a desired self-locking angle α includes providing a cylindrical support having a beveled inner top surface. A beveled edge that defines a conical interface with the beveled inner top surface of the cylindrical support is formed on a bottom surface of the substrate carrier.

A coefficient of friction is measured at the conical interface. The self-locking angle α may be determined from the expression tan α>f, where f is the coefficient of friction measured at the conical interface. A bottom surface of another substrate carrier is then formed at a beveled edge that defines a conical interface with the beveled inner top surface of the cylindrical support at the determined self-locking angle α.

The self-locking angle can also be determined so that it provides for near perfect carrier centering along a rotation axis of the cylindrical support. In one embodiment, the self-locking angle can also be determined so that it provides a small gap at the conical interface at room temperature. In another embodiment, the self-locking angle can be determined so that it provides a substantially zero gap between the substrate carrier and the support at the conical interface at temperatures ranging from about 500° C. to about 900° C. In another embodiment, the self-locking angle can be determined so that it provides a negative gap between the substrate carrier and the rotating support that is less than 0.05 mm at temperatures ranging from about 1000° C. to about 1150′C. The negative gap can result from the beveled edge of the bottom surface of the substrate carrier expanding into the beveled inner top surface of the support.

The substrate carrier can be formed of a material selected from the group consisting of graphite, graphite coated with silicon carbide, graphite coated with tantalum carbide, graphite coated with tungsten carbide, graphite coated with niobium carbide, graphite coated with molybdenum carbide, boron carbide, boron nitride, silicon carbide, tantalum carbide, aluminum carbide, aluminum nitride, niobium carbide, niobium nitride, alumina, molybdenum, and combinations thereof. The substrate carrier can also be formed of a material that has a coefficient of thermal expansion that is similar to the coefficient of thermal expansion of the cylindrical support.

Another method of chemical vapor deposition according to the present teaching includes providing a cylindrical support having a beveled inner top surface. A substrate carrier is provided with a top surface having a recessed area for receiving at least one substrate and a bottom surface having a beveled edge that forms a conical interface with the beveled inner top surface of the support. The angle of the conical interface can be approximately 45 degrees. The conical interface can be formed at a substantially zero gap between the beveled edge of the outer surface of the substrate carrier and the beveled inner top surface of the support at the desired processing temperature. The conical interface can also be formed to provide carrier centering along a rotation axis of the rotating support. The weight of the substrate carrier can be selected so that during processing and purging, the substrate carrier is frictionally attached to a top surface of the rotating support.

The substrate carrier is heated to a desired process temperature for chemical vapor deposition processing. The substrate carrier is rotated at a desired rotation rate that is less than a rotation rate that causes a threshold centripetal force acting in a substrate carrier plane to tilt the substrate carrier. The threshold centripetal force can further results in vertical movement of the substrate carrier. For example, the desired rotation rate can be less than 400 rpms when the desired process temperature is below 600 degrees C.

Processes gasses are introduced into a reaction area proximate to the at least one substrate, thereby forming a chemical vapor deposition reaction on a surface of the at least one substrate.

### EQUIVALENTS

While the applicant's teaching is described in conjunction with various embodiments, it is not intended that the applicant's teaching be limited to such embodiments. On the contrary, the applicant's teaching encompasses various alternatives, modifications, and equivalents, as will be appreciated by those of skill in the art, which may be made therein without departing from the spirit and scope of the teaching.

What is claimed is:

1. A self-centering split substrate carrier that supports a semiconductor substrate in a chemical vapor deposition system, the substrate carrier comprising:
a) a first section configured to be centrally located in the self-centering split substrate carrier, the first section comprising a top surface having a recessed area for receiving at least one substrate for chemical vapor deposition processing and comprising a plurality of apertures positioned in an outer surface; and
b) a second section formed in a ring-shape having an inner surface configured to receive the first section and an outer surface configured to interface with an edge drive rotation mechanism that rotates the self-centering split substrate carrier, the inner surface of the second section comprising a plurality of boss structures, wherein a respective one of the plurality of boss structures on the inner surface of the second section is configured to fit into a respective one of the plurality of apertures positioned in the outer surface of the first section, so as to improve alignment of the first and the second section of the self-centering split substrate carrier.

2. The split substrate carrier of claim 1 wherein the first section is formed in a circular shape.

3. The split substrate carrier of claim 1 wherein at least some of the plurality of boss structures are pins.

4. The split substrate carrier of claim 1 wherein the outer surface of the second section is configured to interface with a rotary drum-type edge drive rotation mechanism.

5. The split substrate carrier of claim 1 wherein the recessed area of the first section of the split substrate carrier supports an entire bottom surface of the at least one substrate.

6. The split substrate carrier of claim 1 wherein the first and the second sections are formed of materials having a same coefficient of thermal expansion.

7. The split substrate carrier of claim 1 wherein the first and the second sections are formed of the same material.

8. The split substrate carrier of claim 1 wherein a respective one of the plurality of boss structures is positioned to interface with a respective one of the plurality of apertures so that the first and second sections are centered concentrically while allowing for radial thermal expansion of the first section relative to the second section.

9. The split substrate carrier of claim 1 wherein a radial clearance between the first and second sections is in the range of 100-500 microns.

10. The split substrate carrier of claim 1 wherein the first and second sections are configured to form a gap between the first section and the second section, wherein the gap is dimensioned to create a labyrinthine gas flow path between the first section and the second section that reduces gas diffusion from a reaction space proximate to top surfaces of the split substrate carrier and a heater volume proximate to a bottom surface bottom surfaces of the split substrate carrier.

11. The split substrate carrier of claim 1 wherein an edge geometry of the second section of the split substrate carrier and the edge geometry of the rotating support are chosen to define a gap therebetween.

12. The split substrate carrier of claim 11 wherein a width of the gap is chosen to approach zero at the desired process temperature.

13. The split substrate carrier of claim 11 wherein a width of the gap changes during heating due to a difference between a coefficient of thermal expansion of a material forming the second section of the split substrate carrier and a coefficient of thermal expansion of a material forming the rotating support.

14. The split substrate carrier of claim 11 wherein a width of the gap at room temperature is chosen so that there is space for thermal expansion of the second section of the split substrate carrier relative to the edge drive rotation mechanism at the desired processing temperature.

15. A method of manufacturing a split substrate carrier that supports at least one semiconductor substrate on a top surface of the split substrate carrier in a chemical vapor deposition system, the method comprising:
a) providing a first section configured to be centrally located in the split substrate carrier, wherein the first section comprises a top surface having a recessed area for receiving at least one substrate for chemical vapor deposition processing and comprising a plurality of apertures positioned in an outer surface;
b) providing a second section formed in a ring-shape having an inner surface configured to receive the first section and an outer surface configured to interface with an edge drive rotation mechanism that rotates the split substrate carrier, wherein the inner surface of the second section comprises a plurality of boss structures; and
c) positioning the first section into the second section, wherein a respective one of the plurality of boss structures on the inner surface of the second section fits into a respective one of the plurality of apertures positioned in the outer surface of the first section so as to improve alignment of the first and the second section of the split substrate carrier.

16. The method of claim 15 further comprising forming the first and second sections of the split substrate carrier with materials that have the same coefficient of thermal expansion.

17. The method of claim 15 further comprising forming the first and second sections of the substrate carrier of a material selected from the group consisting of graphite, graphite coated with silicon carbide, graphite coated with tantalum carbide, graphite coated with tungsten carbide, graphite coated with niobium carbide, graphite coated with molybdenum carbide, boron carbide, boron nitride, silicon carbide, tantalum carbide, aluminum carbide, aluminum nitride, niobium carbide, niobium nitride, alumina, molybdenum, and combinations thereof.

18. The method of manufacturing of claim 15 further comprising forming the split substrate carrier of a material that has a coefficient of thermal expansion that is similar to the coefficient of thermal expansion of the edge drive rotation mechanism.
